(19) United States
(12) Patent Application Publication
(10) Pub. No.: US 2023/0189517 A1
(43) Pub. Date: Jun. 15, 2023

(54) SEMICONDUCTOR DEVICE AND MANUFACTURING METHOD THEREOF

(71) Applicant: Kioxia Corporation, Tokyo (JP)

(72) Inventors: Hiroyuki YAMASAKI, Nagoya Aichi (JP); Hiroshi MATSUMOTO, Yokkaichi Mie (JP); Masahisa SONODA, Yokkaichi Mie (JP); Kiyomitsu YOSHIDA, Mie (JP)

(73) Assignee: Kioxia Corporation, Tokyo (JP)

(21) Appl. No.: 17/897,733

(22) Filed: Aug. 29, 2022

(30) Foreign Application Priority Data
Dec. 15, 2021 (JP) 2021-203372

(51) Int. Cl. H01L 27/11524; H01L 27/11519; H01L 27/11565; H01L 23/522; H01L 23/528; H01L 27/11582; H01L 27/1157; H01L 27/11556

(52) U.S. Cl. CPC H01L 27/11524; H01L 27/11519; H01L 27/11565; H01L 23/5226; H01L 23/5283; H01L 27/11582; H01L 27/1157; H01L 27/11556

(57) ABSTRACT

A semiconductor device includes a plurality of first electrode films stacked in a first direction and electrically isolated from each other; a plurality of semiconductor members extending in the first direction through the plurality of first electrode films; a first conductive film including a first surface and connected to the plurality of semiconductor members on the first surface; a first insulating film spaced from the first conductive film on a second surface of the first conductive film opposite to the first surface; a first edge member disposed in an edge area that surrounds an element area including the first electrode film, the semiconductor member, and the first conductive film; and a conductive first plug provided between the first edge member and the element area in the edge area and is in contact with the first insulating film.

### CROSS-REFERENCE TO RELATED APPLICATION(S)

This application is based upon and claims the benefit of priority from Japanese Patent Application No. 2021-203372, filed Dec. 15, 2021, the entire contents of which are incorporated herein by reference.

### FIELD

Embodiments described herein relate generally to a semiconductor device and a manufacturing method thereof.

### BACKGROUND

A semiconductor device such as a NAND-type flash memory may have a CMOS Bonding Array (CBA) structure in which a memory cell array is bonded above a Complementary Metal Oxide Semiconductor (CMOS) circuit for scaling down. The CBA structure has an advantage that an area occupancy rate of the memory cell array can be enhanced. However, it is desired to allocate a sufficient plug grounding area for static elimination as a countermeasure against arcing in a manufacturing step.

### DESCRIPTION OF THE DRAWINGS

FIG. 1 is a cross-sectional view schematically illustrating a configuration example of a semiconductor device according to a first embodiment.

FIG. 2 is a plan view schematically illustrating a stacked body.

FIG. 3 is a cross-sectional view schematically illustrating a memory cell with a three-dimensional structure.

FIG. 4 is a cross-sectional view schematically illustrating the memory cell with a three-dimensional structure.

FIG. 5 is a plan view schematically illustrating a configuration example of the semiconductor device.

FIG. 6 is a cross-sectional view illustrating configuration examples of a chip area, an edge seal area, and a kerf area.

FIG. 7 is a cross-sectional view more specifically illustrating the configuration example of the edge seal area.

FIG. 8 is a cross-sectional view illustrating an example of a manufacturing method of the semiconductor device according to the first embodiment.

FIG. 9 is a cross-sectional view illustrating an example of the manufacturing method of the semiconductor device subsequently to FIG. 8.

FIG. 10 is a cross-sectional view illustrating an example of the manufacturing method of the semiconductor device subsequently to FIG. 9.

FIG. 11 is a cross-sectional view illustrating an example of the manufacturing method of the semiconductor device subsequently to FIG. 10.

FIG. 12 is a cross-sectional view illustrating an example of the manufacturing method of the semiconductor device subsequently to FIG. 11.

FIG. 13 is a cross-sectional view illustrating an example of the manufacturing method of the semiconductor device subsequently to FIG. 12.

FIG. 14 is a cross-sectional view illustrating an example of the manufacturing method of the semiconductor device subsequently to FIG. 13.

FIG. 15 is a cross-sectional view illustrating an example of the manufacturing method of the semiconductor device subsequently to FIG. 14.

FIG. 16 is a cross-sectional view illustrating an example of the manufacturing method of the semiconductor device subsequently to FIG. 15.

FIG. 17 is a cross-sectional view illustrating an example of the manufacturing method of the semiconductor device subsequently to FIG. 16.

FIG. 18 is a cross-sectional view illustrating an example of the manufacturing method of the semiconductor device subsequently to FIG. 17.

FIG. 19 is a cross-sectional view illustrating an example of the manufacturing method of the semiconductor device subsequently to FIG. 18.

FIG. 20 is a cross-sectional view illustrating a configuration example of a semiconductor device according to a second embodiment.

FIG. 21 is a cross-sectional view illustrating an example of a manufacturing method of the semiconductor device according to the second embodiment.

FIG. 22 is a cross-sectional view illustrating an example of the manufacturing method of the semiconductor device subsequently to FIG. 21.

FIG. 23 is a cross-sectional view illustrating an example of the manufacturing method of the semiconductor device subsequently to FIG. 22.

FIG. 24 is a cross-sectional view illustrating a configuration example of a semiconductor device according to a third embodiment.

FIG. 25 is a plan view illustrating a configuration example of the semiconductor device according to the third embodiment.

FIG. 26 is a cross-sectional view illustrating a configuration example of a semiconductor device according to a fourth embodiment.

FIG. 27 is a cross-sectional view illustrating a configuration example of a semiconductor device according to a fifth embodiment.

FIG. 28 is a cross-sectional view illustrating a configuration example of a semiconductor device according to a sixth embodiment.

FIG. 29 is a plan view illustrating a configuration example of the semiconductor device according to the sixth embodiment.

FIG. 30 is a plan view illustrating a configuration example of the semiconductor device according to the sixth embodiment.

FIG. 31 is a cross-sectional view illustrating a configuration example of a semiconductor device according to a seventh embodiment.

FIG. 32 is a cross-sectional view illustrating an example of a manufacturing method of the semiconductor device according to the seventh embodiment.

FIG. 33 is a cross-sectional view illustrating an example of the manufacturing method of the semiconductor device subsequently to FIG. 32.

FIG. 34 is a cross-sectional view illustrating an example of the manufacturing method of the semiconductor device subsequently to FIG. 33.

FIG. 35 is a cross-sectional view illustrating an example of the manufacturing method of the semiconductor device subsequently to FIG. 34.

FIG. 36 is a cross-sectional view illustrating a configuration example of a semiconductor device according to an eighth embodiment.

FIG. 37 is a block diagram illustrating a configuration example of a semiconductor storage device.

FIG. 38 is a circuit diagram illustrating an example of a circuit configuration of a memory cell array.

### DETAILED DESCRIPTION

Embodiments provide a smaller semiconductor device while allocating a sufficient plug grounding area.

In general, according to one embodiment, a semiconductor device includes a plurality of first electrode films stacked in a first direction and electrically isolated from each other; a plurality of semiconductor members extending in the first direction through the plurality of first electrode films; a first conductive film including a first surface and connected to the plurality of semiconductor members on the first surface; a first insulating film spaced from the first conductive film on a second surface of the first conductive film opposite to the first surface; a first edge member disposed in an edge area that surrounds an element area including the first electrode film, the semiconductor member, and the first conductive film; and a conductive first plug provided between the first edge member and the element area in the edge area and is in contact with the first insulating film.

Embodiments according to the present disclosure will be described with reference to the drawings. The present embodiment is not intended to limit the present disclosure. In the following embodiments, a vertical direction of the semiconductor device indicates a relative direction when a surface on which a semiconductor element is provided is assumed to face an upper direction or a lower direction, and may be different from a vertical direction according to the gravitational acceleration. The drawings are schematic or conceptual, and the ratio of each part or the like is not necessarily the same as the actual one. In the specification and the drawings, the same elements as those described previously related to the already described drawings are denoted by the same reference numerals, and detailed description thereof is omitted as appropriate.

### First Embodiment

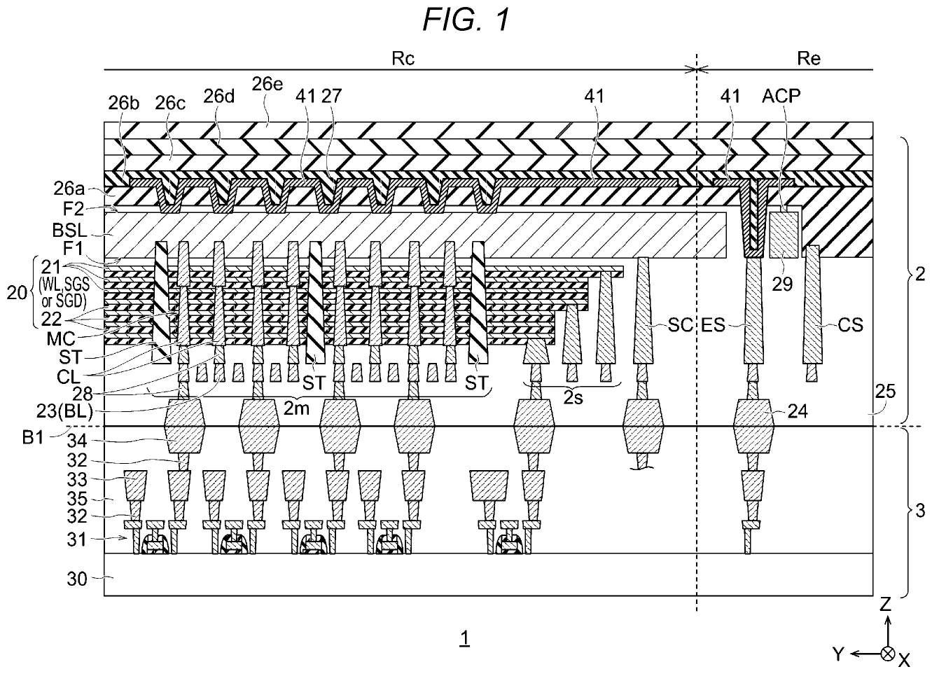

FIG. 1 is a cross-sectional view schematically illustrating a configuration example of a semiconductor device 1 according to a first embodiment. Hereinafter, a stacking direction of a stacked body 20 is defined as a Z direction. One direction that intersects with (for example, orthogonal to) the Z direction is defined as a Y direction. A direction that intersects with (for example, orthogonal to) the Z and Y directions is defined as an X direction.

The semiconductor device 1 includes a memory chip 2 having a memory cell array and a controller chip 3 having a CMOS circuit. The memory chip 2 and the controller chip 3 are bonded to each other on a bonding surface B1, and are electrically connected to each other via wiring bonded on the bonding surface B1. FIG. 1 illustrates a state where the memory chip 2 is mounted on the controller chip 3.

The controller chip 3 includes a substrate 30, a CMOS circuit 31, a via 32, wirings 33 and 34, and an interlayer insulating film 35.

The substrate 30 is, for example, a semiconductor substrate such as a silicon substrate. The CMOS circuit 31 is configured with a transistor provided on the substrate 30. The semiconductor elements such as a resistance element and a capacitive element other than the CMOS circuit 31 may be formed on the substrate 30.

The via 32 electrically connects between the CMOS circuit 31 and the wiring 33, or between the wiring 33 and the wiring 34. The wirings 33 and 34 configure a multilayer wiring structure in the interlayer insulating film 35. The wiring 34 is buried in the interlayer insulating film 35 and is exposed to the front surface of the interlayer insulating film 35 in a substantially flush manner. The wirings 33 and 34 are electrically connected to the CMOS circuit 31 or the like. For example, a low resistance metal such as copper or tungsten is used for the via 32, the wirings 33 and 34. The interlayer insulating film 35 covers and protects the CMOS circuit 31, the via 32, and the wirings 33 and 34. For example, an insulating film such as a silicon oxide film is used for the interlayer insulating film 35.

The memory chip 2 includes the stacked body 20, columnar portions CL, slits ST, a source layer BSL, an interlayer insulating film 25, insulating films 26a, 26b, 26c, 26d, and 26e, a metal pad 27, and a conductive film 41.

The stacked body 20 is provided above the CMOS circuit 31 and positioned in the Z direction with respect to the substrate 30. The stacked body 20 is configured by alternately stacking a plurality of electrode films 21 and a plurality of insulating films 22 along the Z direction. The electrode film 21 includes, for example, a conductive metal such as tungsten. The insulating film 22 includes, for example, the insulating film such as a silicon oxide film. The insulating film 22 insulates the electrode films 21 from each other. That is, the plurality of electrode films 21 are stacked in an insulation state from each other. The number of layers of each of the electrode films 21 and the insulating films 22 is freely selected. The insulating film 22 may be, for example, a porous insulating film or an air gap.

One or the plurality of electrode films 21 at an upper end and a lower end of the stacked body 20 in the Z direction function as a source-side select gate SGS and a drain-side select gate SGD, respectively. The electrode film 21 between the source-side select gate SGS and the drain-side select gate SGD functions as a word line WL. The word line WL is a gate electrode of a memory cell MC. The drain-side select gate SGD is a gate electrode of a drain-side select transistor. The source-side select gate SGS is provided in an upper area of the stacked body 20. The drain-side select gate SGD is provided in a lower area of the stacked body 20. The upper area refers to an area of the stacked body 20 that is closer to the controller chip 3, and the lower area refers to an area of the stacked body 20 that is farther from the controller chip 3 (closer to the conductive films 41 and 42).

The semiconductor device 1 includes a plurality of memory cells MC connected to each other in series between a source-side select transistor and the drain-side select transistor. A structure in which the source-side select transistor, the memory cells MC, and the drain-side select transistor are connected in series is referred to as a “memory string” or a “NAND string”. The memory string is connected to a bit line BL via, for example, a via 28. The bit line BL is wiring 23 that is provided below the stacked body 20 and extends in the X direction (i.e., a direction perpendicular to the sheet of FIG. 1).

A plurality of columnar portions CL are provided in the stacked body 20. The columnar portions CL extends to penetrate the stacked body 20 in the stacking direction of the stacked body 20 (i.e., the Z direction) in the stacked body 20 and are provided from the via 28 connected to the bit line BL to the source layer BSL. An internal configuration of the columnar portion CL will be described below. Further, in the present embodiment, the columnar portion CL has a high aspect ratio and thus is formed in two stages in the Z direction. However, it does not matter even if the columnar portion CL has one stage.

In addition, a plurality of slits ST are provided in the stacked body 20. The slits ST extend in the X direction and penetrate the stacked body 20 in the stacking direction of the stacked body 20 (i.e., the Z direction). The slit ST is filled with the insulating film such as a silicon oxide film, and the insulating film is configured in a plate shape. The slit ST electrically isolates the electrode films 21 of the stacked body 20.

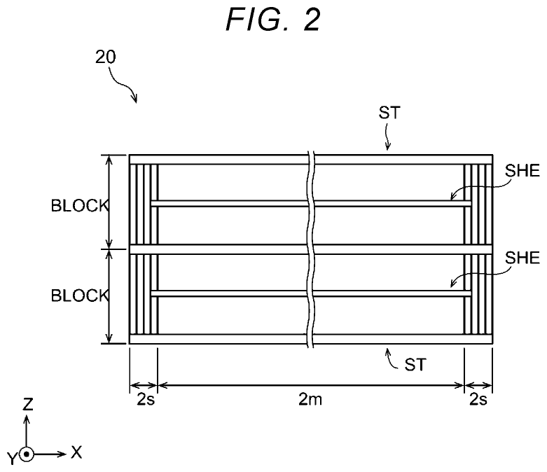

The source layer BSL is provided on the stacked body 20 via the insulating film. The source layer BSL corresponds to the stacked body 20. The source layer BSL includes a first surface F1 and a second surface F2 on a side opposite to the first surface F1. The stacked body 20 is provided on the first surface F1 side of the source layer BSL, and the insulating films 26a to 26e, the metal pad 27, and the conductive films 41 and 42 are provided on the second surface F2 side. The source layer BSL is commonly connected to one ends of the plurality of columnar portions CL and applies a common source voltage to the plurality of columnar portions CL in a same memory cell array 2m. That is, the source layer BSL functions as a common source electrode of the memory cell array 2m. For example, a conductive material such as doped polysilicon is used for the source layer BSL. For example, the low resistance metal such as copper, aluminum, or tungsten is used for the conductive film 41. For example, the insulating film such as a silicon oxide film or a silicon nitride film is used for the insulating films 26a to 26e. The insulating films 26a to 26e are spaced from the source layer BSL. Further, 2s is a step portion of the electrode film 21 for connecting a contact to each of the electrode films 21. The step portion 2s will be described later with reference to FIG. 2.

The metal pad 27 is provided in the insulating film 26a. The metal pad 27 is provided between the source layer BSL and the conductive film 41, and is electrically connected from the conductive film 41 to the source layer BSL.

According to the present embodiment, the memory chip 2 and the controller chip 3 are individually formed and bonded on the bonding surface B1. Accordingly, the CMOS circuit 31 is not provided in the memory chip 2. In addition, the stacked body 20 (i.e., the memory cell array 2m) is not provided in the controller chip 3. The CMOS circuit 31 and the stacked body 20 are on the first surface F1 side of the source layer BSL. The conductive film 41 and the metal pad 27 are on the second surface F2 side.

The conductive film 41 is provided on the insulating film 26a and the metal pad 27 and electrically commonly connected to the metal pad 27. The conductive film 41 can apply a source voltage from the outside of the semiconductor device 1 to the source layer BSL via the metal pad 27. It is preferable that the metal pad 27 substantially evenly corresponds to the stacked body 20 and the source layer BSL in a surface perpendicular to the Z direction (i.e., an X-Y plane). Accordingly, the source voltage may be substantially evenly applied to the source layer BSL.

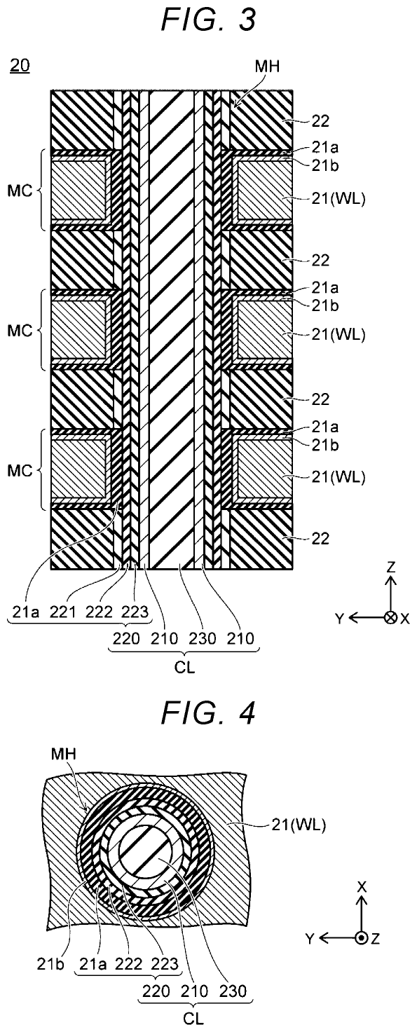

The via 28 and the wirings 23 and 24 are provided below the stacked body 20. The wirings 23 and 24 configure the multilayer wiring structure in the interlayer insulating film 25. The wiring 24 is buried in the interlayer insulating film 25 and is exposed to the front surface of the interlayer insulating film 25 in a substantially flush manner. The wirings 23 and 24 are electrically connected to a semiconductor body 210 of the columnar portion CL or the like (see FIG. 3). For example, the low resistance metal such as copper or tungsten is used for the via 28, and the wirings 23 and 24. The interlayer insulating film 25 covers and protects the stacked body 20, the via 28, and the wirings 23 and 24. For example, the insulating film such as a silicon oxide film is used for the interlayer insulating film 25.

The interlayer insulating film 25 and the interlayer insulating film 35 are bonded to each other on the bonding surface B1, and the wiring 24 and the wiring 34 are bonded to each other on the bonding surface B1 in a substantially flush manner. Therefore, the memory chip 2 and the controller chip 3 are electrically connected to each other via the wirings 24 and 34.

There is an edge seal area Re outside an element area Rc including the memory cell MC (e.g., the stacked body 20 and the columnar portions CL), the slits ST, and the source layer BSL. One or a plurality of edge seals ES are provided in the edge seal area Re. The edge seal ES is provided in a ring shape to surround the element area Rc in the X-Y plane viewed from the Z direction. The edge seal ES extends from the conductive film 41 to the bonding surface B1 in the Z direction, and is electrically connected to the substrate 30 via the wiring 24 or the like. For example, the edge seal ES is configured with the conductive material such as copper or tungsten. Accordingly, the edge seal ES can release (i.e., eliminate) charges to the substrate 30 (i.e., the ground) during a manufacturing process or after the manufacturing. In addition, the edge seal ES can prevent impurities such as hydrogen from intruding to the element area Rc from the outside. Further, in a dicing step, the edge seal ES can prevent cracks or peeling generated from a kerf area (not illustrated) of an outer edge of the chip from propagating to the element area Rc.

One or a plurality of crack stoppers CS are provided further outside the edge seal ES when viewed from the element area Rc. In the X-Y plane viewed from the Z direction, the crack stopper CS is provided in a ring shape to surround the element area Rc and the edge seal ES. The crack stopper CS extends from conductive films 29 and 41 or the insulating film 26a to the bonding surface B1 in the Z direction. In the same manner as the edge seal ES, the crack stopper CS is configured, for example, with the conductive material such as copper or tungsten. The crack stopper CS may be formed in the same manufacturing step as the edge seal ES. Here, as illustrated in FIG. 1, the crack stopper CS may not be electrically connected to the substrate 30. In this case, the crack stopper CS does not have a static elimination function, but may have a function as a crack stopper that prevents intrusion of impurities such as hydrogen and propagation of cracks or peeling.

When viewed from the Z direction, one or a plurality of static elimination plugs ACP are provided between the edge seal ES and the crack stopper CS in the edge seal area Re. When the edge seal ES is not provided, the static elimination plug ACP is provided between the element area Rc and the crack stopper CS. The static elimination plug ACP is provided between the conductive film 29 configured with the same layer as the source layer BSL and the insulating film 26a. The static elimination plug ACP may be formed in a step of forming the source layer BSL. Accordingly, the static elimination plug ACP is configured with the same conductive material (e.g., doped polysilicon) as the source layer BSL and the conductive film 29.

The static elimination plug ACP is provided in a ring shape to surround the element area Rc, between the edge seal ES and the crack stopper CS in the X-Y plane viewed from the Z direction. The static elimination plug ACP projects from the conductive film 29 to the insulating film 26a in the Z direction and is in contact with the insulating film 26a or 26b. The static elimination plug ACP is in an electrically floating state in a finished product, and is not electrically connected to the substrate 30, generally. Therefore, the static elimination plug ACP does not have the static elimination function in the finished product. However, as described below, in the course of the manufacturing step, the static elimination plug ACP has the static elimination function of removing charges accumulated in the source layer BSL and the conductive film 29. In addition, the static elimination plug ACP may have a function as a crack stopper that prevents propagation of cracks or peeling. Further, the configuration and the function of the static elimination plug ACP are specifically described below.

FIG. 2 is a plan view schematically illustrating the stacked body 20. The stacked body 20 includes the step portions 2s and the memory cell array 2m. The step portions 2s are provided in edge portions of the stacked body 20. The memory cell array 2m is interposed between or surrounded by the step portion 2s. The slit ST is provided from the step portion 2s at one end of the stacked body 20 to the step portion 2s at the other end of the stacked body 20 via the memory cell array 2m. A slit SHE is provided at least in the memory cell array 2m. The slits SHE are shallower than the slits ST, and extend substantially parallel to the slits ST. The slits SHE are provided in order to electrically isolate the electrode films 21 per the drain-side select gate SGD.

A portion of the stacked body 20 interposed between the two slits ST illustrated in FIG. 2 is referred to as a block. The block configures, for example, a minimum unit for erasing data. The slits SHE are provided in the block. The stacked body 20 between the deep slit ST and the shallow slit SHE is referred to as a finger. The drain-side select gates SGD are separated per finger. Therefore, at the time of writing and reading data, one finger in the block can enter a selection state by the drain-side select gate SGD.

FIGS. 3 and 4 are cross-sectional views each schematically illustrating an example of the memory cell having a three-dimensional structure. The plurality of columnar portions CL are respectively provided in memory holes MH provided in the stacked body 20. Each columnar portion CL penetrates the stacked body 20 from an upper end of the stacked body 20 along the Z direction, and is provided in the stacked body 20 and in the source layer BSL. The plurality of columnar portions CL each include the semiconductor body 210, a memory film 220, and a core layer 230. The columnar portion CL includes the core layer 230 provided in a central portion thereof, the semiconductor body (semiconductor member) 210 provided around the core layer 230, and the memory film (charge storage member) 220 provided around the semiconductor body 210. The semiconductor body 210 extends in the stacking direction (the Z direction) in the stacked body 20. The semiconductor body 210 is electrically connected to the source layer BSL. The memory film 220 is provided between the semiconductor body 210 and the electrode films 21, and includes a charge storage portion. The plurality of columnar portions CL selected one by one from respective fingers are commonly connected to one bit line BL via the via 28 of FIG. 1. The columnar portions CL are provided, for example, in an area of the memory cell array 2m, respectively.

As illustrated in FIG. 4, a shape of the memory hole MH in the X-Y plane is, for example, a circle or an ellipse. A block insulating film 21a that configures a portion of the memory film 220 may be provided between the electrode film 21 and the insulating film 22. The block insulating film 21a is, for example, a silicon oxide film or a metal oxide film. One example of the metal oxide is aluminum oxide. A barrier film 21b may be provided between the electrode film 21 and the insulating film 22 and between the electrode film 21 and the memory film 220. For example, when the electrode film 21 is tungsten, a stacked structure film including titanium nitride and titanium is selected as the barrier film 21b, for example. The block insulating film 21a prevents back tunneling of charges from the electrode film 21 to the memory film 220 side. The barrier film 21b improves adhesion between the electrode film 21 and the block insulating film 21a.

A shape of the semiconductor body 210 as the semiconductor member is, for example, a cylindrical shape having a bottom. For example, polysilicon is used for the semiconductor body 210. The semiconductor body 210 is, for example, undoped silicon. In addition, the semiconductor body 210 may be p-type silicon. The semiconductor body 210 becomes a channel of each of the drain-side select transistor STD, the memory cell MC, and the source-side select transistor STS. One ends of the plurality of semiconductor bodies 210 in the same memory cell array 2m are electrically commonly connected to the source layer BSL.

In the memory film 220, portions other than the block insulating films 21a are provided between an inner wall of the memory hole MH and the semiconductor body 210. A shape of the memory film 220 is, for example, a cylindrical shape. The plurality of memory cells MC include storage areas between the semiconductor body 210 and the electrode films 21 to be the word lines WL and are stacked in the Z direction. The memory film 220 includes, for example, a cover insulating film 221, a charge storage film 222, and a tunnel insulating film 223. The semiconductor body 210, the charge storage film 222, and the tunnel insulating film 223 each extend in the Z direction.

The cover insulating film 221 is provided between the insulating films 22 and the charge storage film 222. The cover insulating film 221 includes, for example, silicon oxide. The cover insulating film 221 protects the charge storage film 222 not to be etched when sacrificial films (not illustrated) are replaced with the electrode films 21 (i.e., the replacement step). In the replacement step, the cover insulating film 221 may be removed from a portion between the electrode film 21 and the charge storage film 222. In this case, as illustrated in FIGS. 3 and 4, for example, the block insulating films 21a are provided between the electrode films 21 and the charge storage film 222. In addition, when the replacement step is not used for forming the electrode films 21, the cover insulating film 221 may not be provided.

The charge storage film 222 is provided between each of the block insulating film 21a and the cover insulating film 221, and the tunnel insulating film 223. The charge storage film 222 includes, for example, silicon nitride and has a trap site that traps charges in the film. Portions of the charge storage film 222 that are interposed between the electrode films 21 to be the word lines WL and the semiconductor body 210 configure storage areas of the memory cell MC as the charge storage portions. A threshold voltage of the memory cell MC changes depending on presence or absence of charges in the charge storage portion or an amount of charges captured in the charge storage portion. Accordingly, the memory cell MC stores information.

The tunnel insulating film 223 is provided between the semiconductor body 210 and the charge storage film 222. The tunnel insulating film 223 includes, for example, silicon oxide, or silicon oxide and silicon nitride. The tunnel insulating film 223 is a potential barrier between the semiconductor body 210 and the charge storage film 222. For example, when electrons are injected from the semiconductor body 210 to the charge storage portion (i.e., a write operation), and when holes are injected from the semiconductor body 210 to the charge storage portion (i.e., an erasing operation), the electrons and holes each pass through the potential barrier of the tunnel insulating film 223 (i.e., tunneling).

The core layer 230 fills an internal space of the semiconductor body 210 having a cylindrical shape. The shape of the core layer 230 is, for example, a columnar shape. The core layer 230 includes, for example, silicon oxide and has insulating properties.

The stacked body 20 and the memory cell array 2m of the memory chip 2 are configured in this manner.

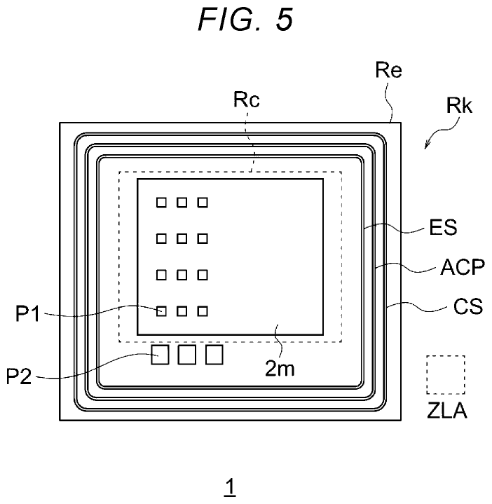

FIG. 5 is a plan view schematically illustrating a configuration example of the semiconductor device 1. FIG. 5 illustrates a planar layout viewed from the Z direction. The semiconductor device 1 is configured as one semiconductor chip. There is a chip area Rc in a central portion of the semiconductor device 1. The edge seal area Re that surrounds the chip area Rc is provided. A kerf area Rk surrounds the edge seal area Re. An outer edge of the semiconductor chip is formed by cutting the kerf area Rk in the dicing step, and positioned between or near the edge seal area Re and the kerf area Rk.

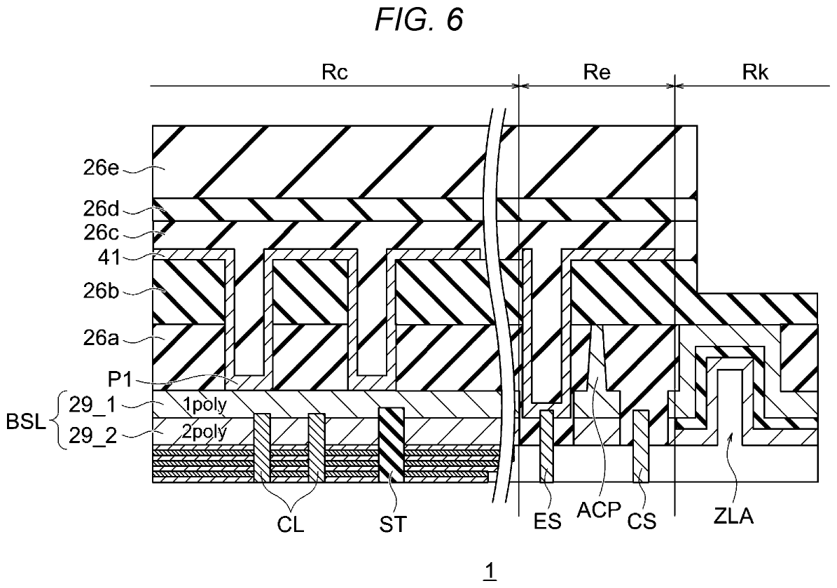

The memory cell array 2m is provided in the chip area Rc. Backing pads P1 formed with the conductive film 41 are provided on the source layer BSL under the memory cell array 2m. As illustrated in FIG. 6, the backing pads P1 are electrically connected to each other by the conductive film 41, and substantially evenly apply the source voltage to the source layer BSL. Penetrating via pads P2 are provided outside the chip area Rc, and are provided for electrically connecting to other semiconductor chips when the other semiconductor chips are stacked.

The edge seal ES, the static elimination plug ACP, and the crack stopper CS are provided in the edge seal area Re, to surround the chip area Rc. The edge seal ES, the static elimination plug ACP, and the crack stopper CS are located from the chip area Rc to the kerf area Rk in this order.

A mark ZLA for alignment used in a lithography step or the like is provided in the kerf area Rk. The kerf area Rk is an area between semiconductor chips adjacent to each other in a semiconductor wafer state and is an area that is cut when the semiconductor chip is fragmented in the dicing step.

The edge seal area Re is provided along an outer edge of the chip area Rc to surround the chip area Rc. The chip area Rc has, for example, a substantially quadrangular shape, and the edge seal area Re has a substantially square frame shape surrounding the chip area Rc. The kerf area Rk is provided further outside the edge seal area Re. The kerf area Rk is an area cut in the dicing step and may partially remain at an outer edge of the edge seal area Re, but may be blown off by a dicing cutter or the like and disappear.

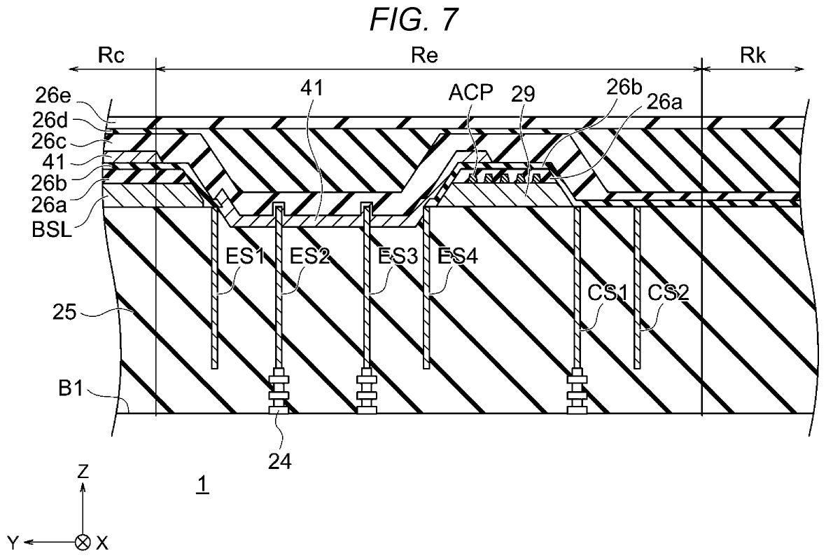

FIG. 6 is a cross-sectional view schematically illustrating configuration examples of the chip area Rc, the edge seal area Re, and the kerf area Rk. FIG. 7 is a cross-sectional view more specifically illustrating the configuration example of the edge seal area Re. Further, in FIG. 7, the stacked body 20 and the controller chip 3 of the chip area Rc are not illustrated.

The static elimination plug ACP of the edge seal area Re projects from the conductive film 29 configured in the same layer as the source layer BSL in the Z direction. The static elimination plug ACP is provided between the conductive film 29 and the insulating film 26a or 26b and is in contact with the insulating film 26a or 26b. In FIGS. 5 and 6, a single static elimination plug ACP is illustrated, but the plurality of static elimination plugs ACP may be located from the inside of the edge seal area Re to the outside in the Y direction as illustrated in FIG. 7. The conductive film 29 is electrically isolated from the source layer BSL, but is configured in the same layer and with the same material as the source layer BSL.

Further, the source layer BSL becomes a stacked structure of conductive films 29_1 and 29_2. The conductive film 29_1 is closer to the insulating films 26a to 26e than the conductive film 29_2. In the first embodiment, the static elimination plug ACP is configured with the conductive film 29_1 closer to the insulating films 26a to 26e.

A width of the static elimination plug ACP in a direction (i.e., an arrangement direction of the static elimination plugs ACP: the Y direction) substantially perpendicular to the Z direction becomes narrower as approaching the insulating films 26a and 26b from the conductive film 29. That is, a side surface of the static elimination plug ACP has a forward taper and has a tapered shape. For example, a material such as doped polysilicon is used for the static elimination plug ACP.

In addition, in FIGS. 5 and 6, a single edge seal ES is illustrated, but a plurality of edge seals ES1 to ES4 may be provided as illustrated in FIG. 7. The edge seals ES1 to ES4 surround the chip area Rc in the edge seal area Re in a plan view seen from the Z direction, and are provided outside the chip area Rc and inside crack stoppers CS1 and CS2. The edge seals ES1 to ES4 extend in the Z direction in the interlayer insulating film 25.

The edge seals ES1 and ES4 are dummy and are not grounded. Meanwhile, one ends of the edge seals ES2 and ES3 each are electrically connected to the substrate 30 of the controller chip 3 via the wiring 24, and grounded. The other ends of the edge seals ES2 and ES3 each are commonly electrically connected to the conductive film 41.

Further, FIGS. 5 and 6 illustrate a single crack stopper CS. However, the plurality of crack stoppers CS1 and CS2 may be provided as illustrated in FIG. 7. The crack stoppers CS1 and CS2 surround the edge seals ES1 to ES4 in the edge seal area Re in a planar layout viewed from the Z direction, and are provided outside the edge seals ES1 to ES4. The crack stoppers CS1 and CS2 extend in the Z direction in the interlayer insulating film 25. Further, as illustrated in FIG. 6, an upper end of the crack stopper CS may be in contact with the insulating film 26a and may be in contact with the insulating film 26b as illustrated in FIG. 7.

The crack stoppers CS1 and CS2 prevent cracks or peeling. Accordingly, the both may be electrically floating state like the crack stopper CS2. Meanwhile, even if the both are electrically connected to the substrate 30 of the controller chip 3 and grounded like the crack stopper CS1, there is no problem with a function as a crack stopper.

In a plan view seen from the Z direction, the static elimination plug ACP is provided between the edge seals ES1 to ES4 and the crack stoppers CS1 and CS2 in the edge seal area Re. In addition, the static elimination plug ACP is provided above the edge seals ES1 to ES4 and the crack stoppers CS1 and CS2 in the Z direction. Meanwhile, the conductive film 41 that electrically connects the edge seals ES2 and ES3 to each other extends above the static elimination plug ACP and is provided on the static elimination plug ACP.

A material (i.e., the conductive film 29) of the source layer BSL on the edge seals ES1 to ES4 and the crack stoppers CS1 and CS2 is removed. Accordingly, the source layer BSL of the chip area Rc and the conductive film 29 under the static elimination plug ACP are isolated. Meanwhile, the edge seals ES2 and ES3 are electrically connected to each other by the conductive film 41.

The edge seals ES1 to ES4 and the crack stoppers CS1 and CS2 may be formed simultaneously in a step of forming a source contact SC of FIG. 1. Accordingly, the same conductive material (e.g., copper or tungsten) as that for the source contact SC is used for the edge seals ES1 to ES4 and the crack stoppers CS1 and CS2.

As illustrated in FIG. 6, the mark ZLA is provided in the kerf area Rk. The kerf area Rk may be blown off in the dicing step. Accordingly, the mark ZLA does not necessarily remain. In the same manner as the static elimination plug ACP, the mark ZLA projects toward the insulating film 26a or 26b and is in contact with the insulating film 26a or 26b. The mark ZLA includes the same material as the conductive film 29. However, the mark ZLA is provided in the kerf area Rk and provided on an outer side of the edge seal ES and the crack stopper CS. In addition, the mark ZLA includes not only the conductive film 29, but also other insulating film, sacrificial film, and conductive layer for the use in the alignment of the lithography step.

According to the present embodiment, the static elimination plug ACP is provided in the edge seal area Re. The static elimination plug ACP is provided between the crack stopper CS and the chip area Rc. Further, the static elimination plug ACP is provided between the crack stopper CS and the edge seal ES. The static elimination plug ACP projects from the conductive film 29, and a tip thereof is in contact with the insulating film 26a or 26b. The insulating films 26a and 26b are materials formed after a substrate (not illustrated) is removed in the manufacturing step described below. Accordingly, the static elimination plug ACP is connected to the substrate in the course of the manufacturing step, and has a function of releasing charges accumulated in the conductive film 29 to the substrate. Accordingly, in a step of forming a deep hole or a groove such as the memory hole MH or the slit ST, the static elimination plug ACP can eliminate the charges accumulated in the conductive film 29. As a result, arcing from the conductive film 29 can be prevented.

In addition, since the static elimination plug ACP according to the present embodiment is provided, it is not required to connect the conductive film 29 to the substrate in a bevel area of the edge seal area Re or the kerf area Rk for grounding. A relatively large area is required for the grounding of the conductive film 29 in the bevel area. In contrast, the static elimination plug ACP needs a relatively small area. Therefore, the static elimination plug ACP can scale down the semiconductor chip and reduce a manufacturing cost while the grounding area of the conductive film 29 is allocated.

Subsequently, a manufacturing method of the semiconductor device 1 according to the present embodiment will be described.

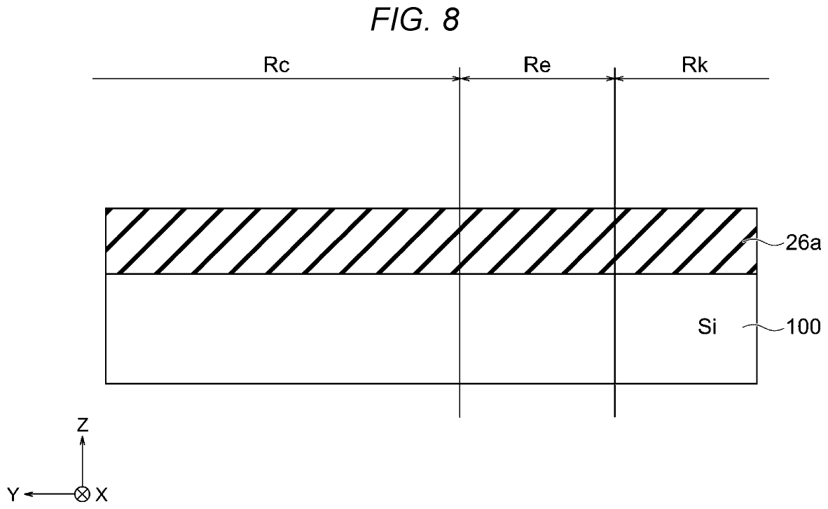

FIGS. 8 to 19 are cross-sectional views illustrating examples of the manufacturing method of the semiconductor device 1 according to the first embodiment. First, as illustrated in FIG. 8, the insulating film 26a is formed on a substrate 100 on the memory cell array 2m side. For example, a silicon substrate is used for the substrate 100. For example, a silicon oxide film such as a Tetra Ethoxy Silane (TEOS) film is used for the insulating film 26a.

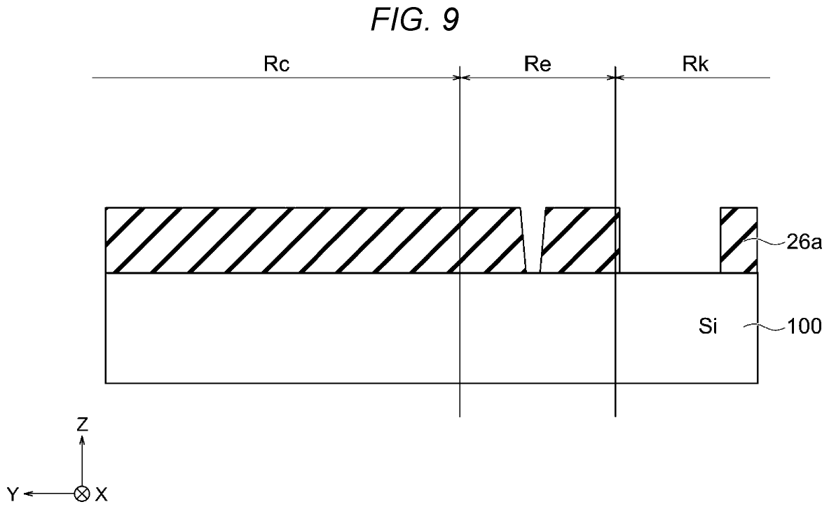

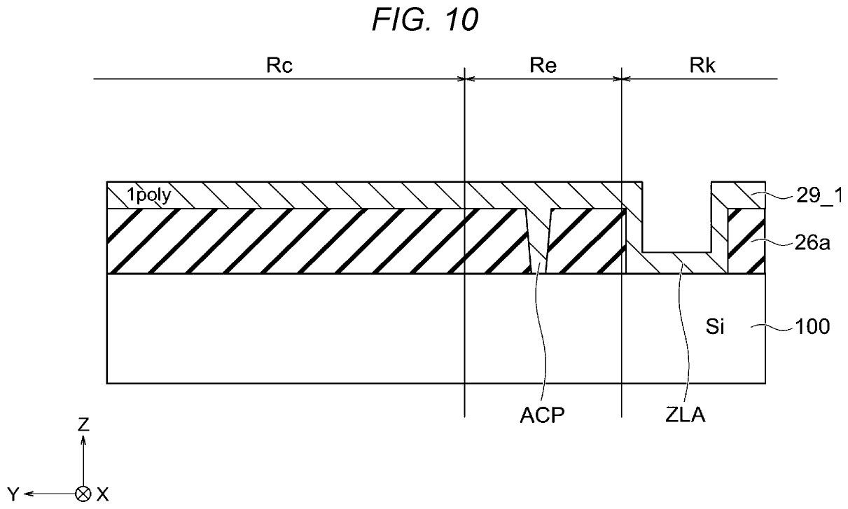

Subsequently, as illustrated in FIG. 9, by using the lithography technique and the etching technique, the insulating film 26a in formation areas of the static elimination plug ACP and the mark ZLA is removed. In the formation areas of the static elimination plug ACP and the mark ZLA, grooves are formed, and the substrate 100 is exposed. The formation area of the static elimination plug ACP becomes narrower in a width in the direction substantially perpendicular to the Z direction (i.e., the Y direction) as approaching the substrate 100, and thus is tapered toward the substrate 100. That is, a side wall of the groove of the formation area of the static elimination plug ACP is formed in a forward taper shape.

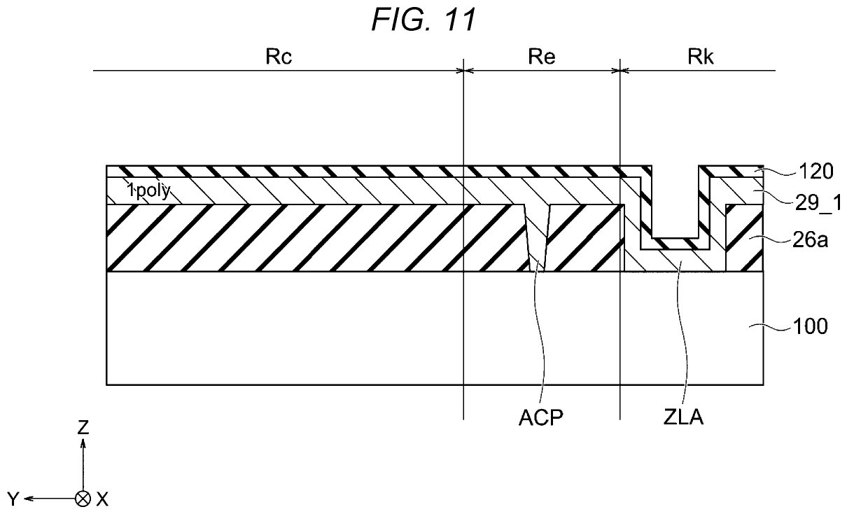

Subsequently, as illustrated in FIG. 10, the conductive film 29_1 is formed on the insulating film 26a and the substrate 100. The conductive film 29_1 is a portion of the conductive film 29, that is, the source layer BSL. For example, the conductive material such as doped polysilicon is used for the conductive film 29_1. The conductive film 29_1 fills the formation area of the static elimination plug ACP, and covers an inner wall of the formation area of the mark ZLA so that the groove thereof is not filled. Accordingly, in the formation areas of the static elimination plug ACP and the mark ZLA, the conductive film 29_1 that is electrically connected to the substrate 100 is formed. The static elimination plug ACP is electrically connected between the conductive film 29_1 and the substrate 100. In addition, the conductive film 29_1 does not fill the groove of the formation area of the mark ZLA, and thus the mark ZLA functions as an alignment mark in the next lithography step.

Depending on a shape of the groove in the formation area of the static elimination plug ACP, the static elimination plug ACP also becomes narrower in the width in the direction substantially perpendicular to the Z direction (i.e., the Y direction) as approaching the substrate 100, and thus is also tapered toward the substrate 100. That is, the static elimination plug ACP is formed in a forward taper shape.

In addition, the width of the static elimination plug ACP in the Y direction is preferably caused to be equal to or less than twice of a film thickness of the conductive film 29_1. When the film thickness of the conductive film 29_1 is, for example, about 100 nm, the width of the static elimination plug ACP is preferably about 200 nm or less. Accordingly, the material of the conductive film 29_1 can fill a groove of the static elimination plug ACP, the conductive film 29_1 is not much recessed and becomes relatively flat. Accordingly, the conductive film 29_2 and the interlayer insulating film 25 formed on the conductive film 29_1 become relatively flat, and thus a flattening step (e.g., a chemical mechanical polishing (CMP) step) can be omitted.

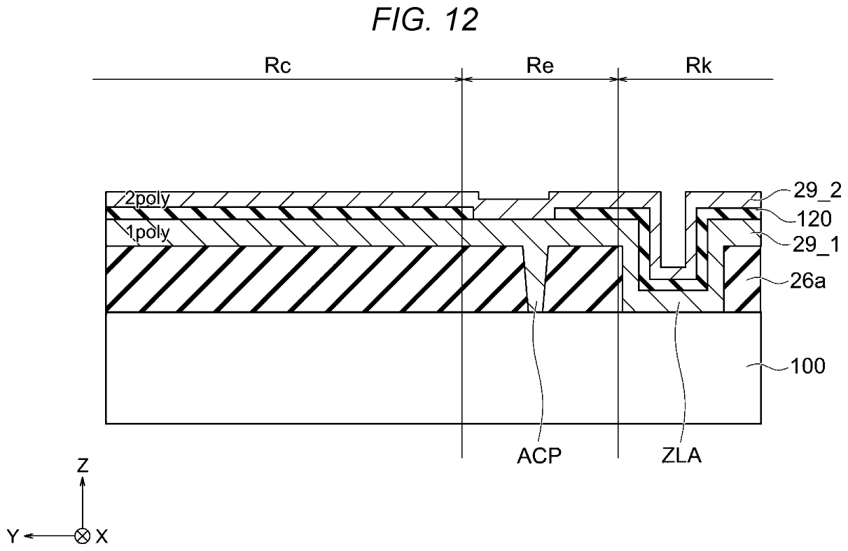

Next, as illustrated in FIG. 11, an insulating film 120 is formed on the conductive film 29_1. The insulating film 120 may be, for example, a stacked film including a silicon oxide film, a silicon nitride film, and a silicon oxide film (i.e., an ONO film). The insulating film 120 is a sacrificial film or the like to be used for connecting the source layer BSL to the columnar portion CL, and is removed from the chip area Rc in the subsequent steps.

Next, by using the lithography technique and the etching technique, a portion of the insulating film 120 is removed. Next, as illustrated in FIG. 12, the conductive film 29_2 is formed on the insulating film 120 and the conductive film 29_1. The conductive film 29_2 is another portion of the conductive film 29, that is, the source layer BSL. In the same manner as the conductive film 29_1, for example, the conductive material such as doped polysilicon is used for the conductive film 29_2. Since the formation area of the static elimination plug ACP is already filled with the conductive film 29_1, the conductive film 29_2 covers the relatively flat conductive film 29_1. The formation area of the mark ZLA is not filled with the conductive film 29_1, and the conductive film 29_2 also covers an inner wall of the formation area of the mark ZLA, together with the insulating film 120. In this manner, the static elimination plug ACP is configured with the conductive film 29_1 closer to the substrate 100 than the conductive film 29_2.

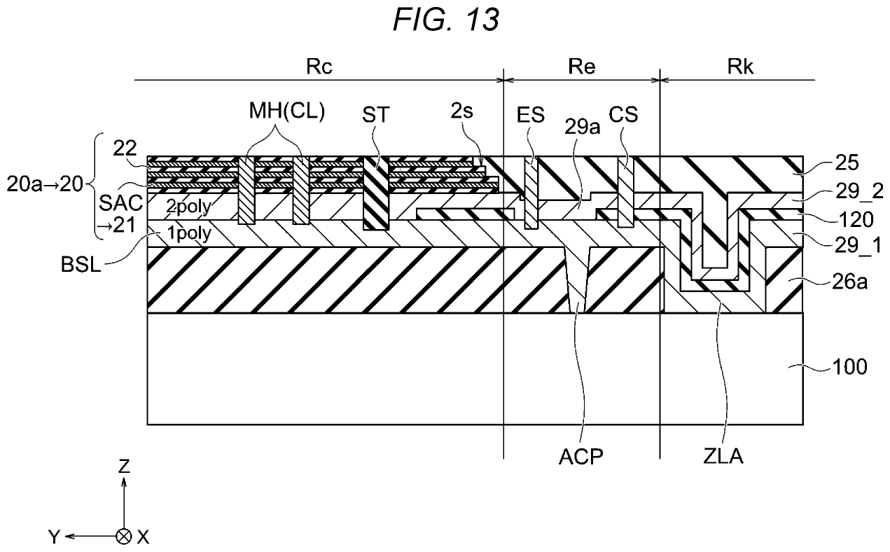

Next, as illustrated in FIG. 13, the plurality of insulating films (i.e., stacked insulating films) 22 and a plurality of sacrificial films SAC are alternately stacked on the conductive film 29_2. For example, the insulating film such as a silicon oxide film is used for the insulating film 22. For example, the insulating film such as a silicon nitride film, which can be etched with respect to the insulating film 22 is used for the sacrificial film SAC. Further, a stacked body including the stacked insulating films 22 and the sacrificial films SAC is hereinafter referred to as a stacked body 20a.

Next, an end portion of the stacked body 20a is processed in a step shape, to form the step portion 2s. Next, the plurality of memory holes MH that penetrate the stacked body 20a in the stacking direction (i.e., the Z direction) and reach the conductive films 29_1 and 29_2 are formed. In the memory holes MH, the memory film 220, the semiconductor body 210, and the core layer 230, which are described with reference to FIGS. 3 and 4, are formed in each of the memory holes MH. Accordingly, the columnar portions CL penetrate the stacked body 20a in the stacking direction thereof. The columnar portions CL reach the conductive films 29_1 and 29_2. Further, according to the present embodiment, the memory holes MH and the columnar portions CL may be formed in two stages in an upper portion and a lower portion of the stacked body 20a and may be formed in one stage with respect to the stacked body 20a.

Here, in an etching step of forming the memory holes MH, when the memory holes MH reach the conductive films 29_1 and 29_2, charges are accumulated in the conductive films 29_1 and 29_2.

If the static elimination plug ACP is not provided, the conductive films 29_1 and 29_2 enter the electrically floating state and are charged by charges by the etching. The charges accumulated in the conductive films 29_1 and 29_2 cause arcing with the substrate 100 or other configurations. To deal with this, the conductive films 29_1 and 29_2 can be electrically connected to the static elimination plug ACP provided in the edge seal area Re, to release the charges to the substrate 100 via the static elimination plug ACP. Accordingly, the static elimination plug ACP can prevent the conductive films 29_1 and 29_2 from causing arcing with the other configurations by preventing the conductive films 29_1 and 29_2 from entering the electrically floating state.

Further, the alignment mark ZLA in the kerf area Rk is used for the alignment in the lithography step, and thus is not necessarily connected to the conductive films 29_1 and 29_2 and the substrate 100. In addition, the alignment mark ZLA is a very small portion around the chip area Rc and is not considered to be sufficient for the static elimination.

According to the present embodiment, as illustrated in FIG. 13, a connection portion 29a is provided in an end portion of the insulating film 120 (the edge seal area Re), and thus the conductive films 29_1 and 29_2 are electrically connected to each other. Accordingly, during the formation of the memory holes MH, when the conductive film 29_2 is etched, the charges accumulated in the conductive film 29_2 can flow through the conductive film 29_1 via the connection portion 29a. These charges can flow through the substrate 100 via the static elimination plug ACP. That is, the connection portion 29a can prevent the conductive film 29_2 from causing arcing with the other configurations by preventing the conductive film 29_2 from entering the electrically floating state.

Next, the interlayer insulating film 25 is formed on the stacked body 20a. Next, the slits ST are formed in the stacked body 20a. The slits ST penetrate the stacked body 20a in the Z direction and reach the conductive films 29_1 and 29_2. The slits ST extend in the X direction and divide the stacked body 20a to correspond to each block, as described with reference to FIG. 2. Simultaneously with the formation of the slits ST, the crack stopper CS and the edge seal ES may be formed.

Also in an etching step of forming the slits ST, when the slit ST reaches the conductive film 29_1 or 29_2, charges are accumulated in the conductive film 29_1 or 29_2. Accordingly, in the same manner as the etching step of the memory holes MH, it is concerned that arcing is a problem.

However, according to the present embodiment, since the static elimination plug ACP that electrically connects the conductive films 29_1 and 29_2 to the substrate 100 is provided, the charges accumulated in the conductive films 29_1 and 29_2 can flow through the substrate 100 via the static elimination plug ACP. Accordingly, in the step of forming the slits ST, arcing can be prevented.

In addition, the connection portion 29a is provided in the end portion of the insulating film 120, and thus the conductive films 29_1 and 29_2 are electrically connected to each other. Accordingly, during the formation of the slits ST, the charges accumulated in the conductive film 29_2 can flow through the conductive film 29_1 via the connection portion 29a. Accordingly, in the step of forming the slits ST, it is possible to prevent the conductive film 29_2 from causing arcing with the other configurations.

The insulating film 120 is replaced with a conductive film via the slits ST. That is, the insulating film 120 is removed by etching, and a space where the insulating film 120 has been present is filled with a material of the conductive film. The material of the filled conductive film may be the same material as the conductive films 29_1 and 29_2, and is, for example, the conductive material such as doped polysilicon. Accordingly, the conductive films 29_1 and 29_2 are integrated with the filled conductive films instead of the insulating film 120 to be the source layer BSL. In addition, at this point, the memory film 220 on a side surface of the columnar portion CL is removed via the slit ST, so that the conductive films 29_1 and 29_2 are electrically connected to the semiconductor body 210 of the columnar portion CL. Accordingly, the source layer BSL is electrically connected to the semiconductor body 210 of the columnar portion CL.

Next, the sacrificial films SAC of the stacked body 20a are replaced with the electrode films 21 via the slits ST. That is, the sacrificial films SAC are removed by etching, and spaces where the sacrificial films SAC have been present are filled with a material of the electrode film 21. The filling material of the electrode films 21 is, for example, the low resistance metal such as tungsten. Next, the slit ST is filled with the insulating film such as a silicon oxide film. Accordingly, as illustrated in FIG. 13, the stacked body 20 obtained by alternately stacking the plurality of electrode films 21 and the plurality of insulating films 22 is formed. Next, though not illustrated, the multilayer wiring structure is formed on the stacked body 20.

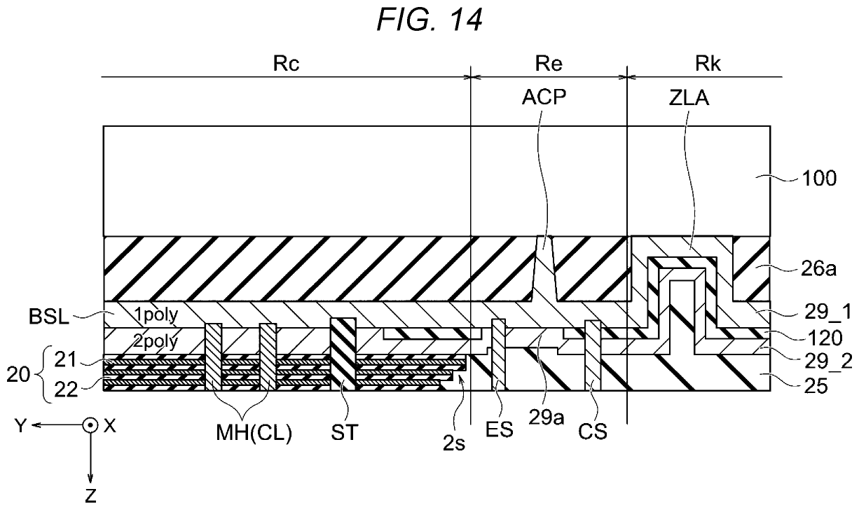

Next, as illustrated in FIG. 14, the memory chip 2 is turned upside down, to bond a surface on the stacked body 20 side to the controller chip 3 on the bonding surface B1 illustrated in FIG. 1. Further, in FIG. 14, the illustration of the controller chip 3 is omitted.

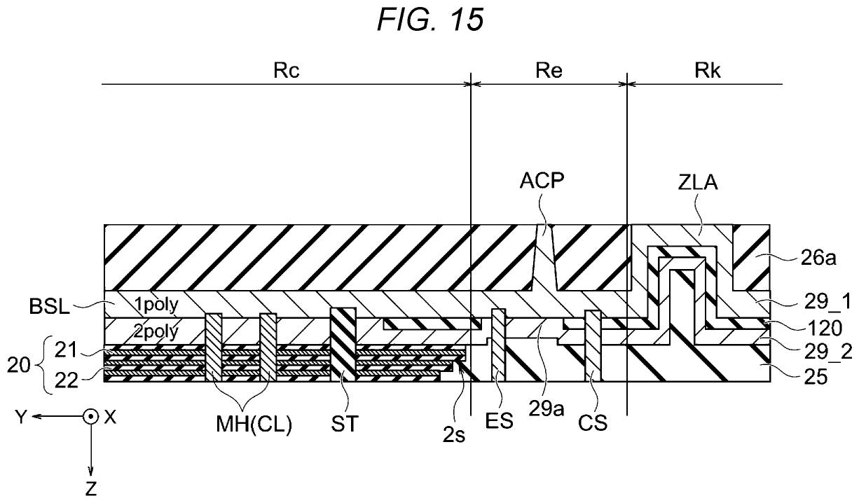

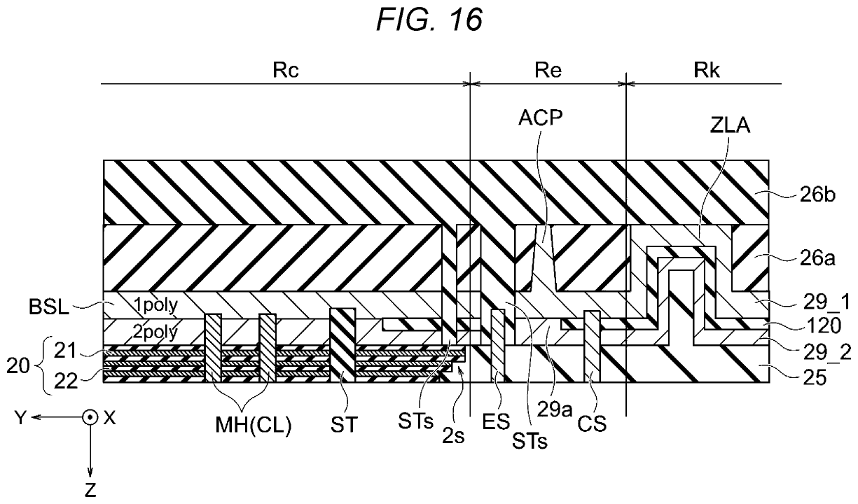

Next, as illustrated in FIG. 15, the substrate 100 is removed by using a CMP method or the like. Accordingly, an upper surface of the static elimination plug ACP and an upper surface of the alignment mark ZLA are exposed.

Next, as illustrated in FIG. 16, by using the lithography technique and the etching technique, in order to electrically isolate the source layer BSL of the chip area Rc from the conductive film 29 of the edge seal area Re, isolation slits STs are formed. At this point, the conductive film 29 of the edge seal area Re to which the static elimination plug ACP is provided is also electrically isolated from the source layer BSL by the isolation slit STs. Accordingly, the static elimination plug ACP is electrically isolated from the source layer BSL. Next, the insulating film 26b is deposited on the insulating film 26a. At this point, as illustrated in FIG. 16, the isolation slit STs is filled with the insulating film 26a. For example, the insulating film such as a silicon oxide film is used for the insulating films 26a and 26b.

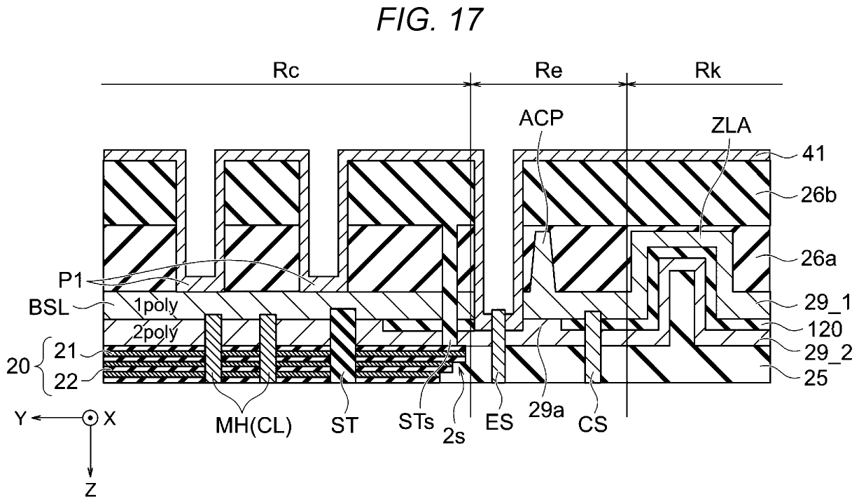

Next, by using the lithography technique and the etching technique, as illustrated in FIG. 17, holes or grooves are formed in formation areas of the backing pads P1 and an area of the edge seal ES in FIG. 5. These holes or grooves reach the source layer BSL and the edge seal ES. A metal layer 41 is formed on an inner wall of these holes or grooves. The metal layer 41 is electrically connected to the source layer BSL and the edge seal ES. For example, the low resistance metal such as copper, aluminum, or tungsten is used for the metal layer 41.

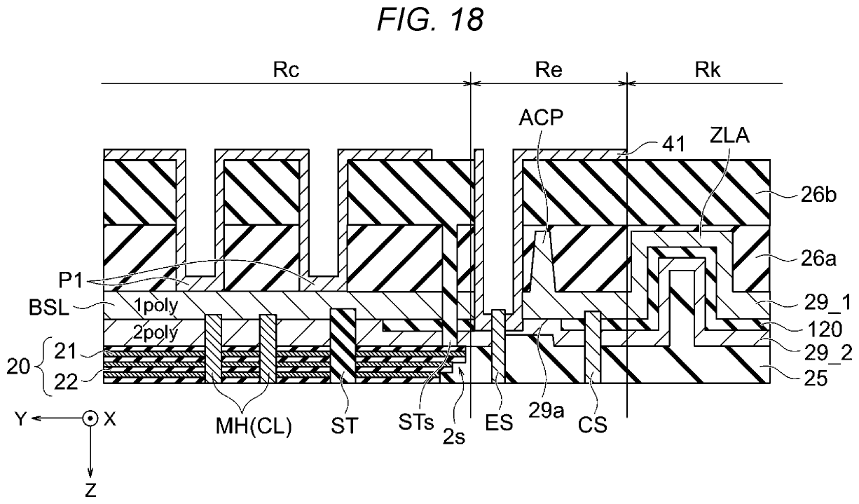

Next, by using the lithography technique and the etching technique, as illustrated in FIG. 18, the metal layer 41 is processed. Accordingly, the metal layer 41 connected to the backing pads P1 and the metal layer 41 connected to the edge seal ES are electrically isolated from each other.

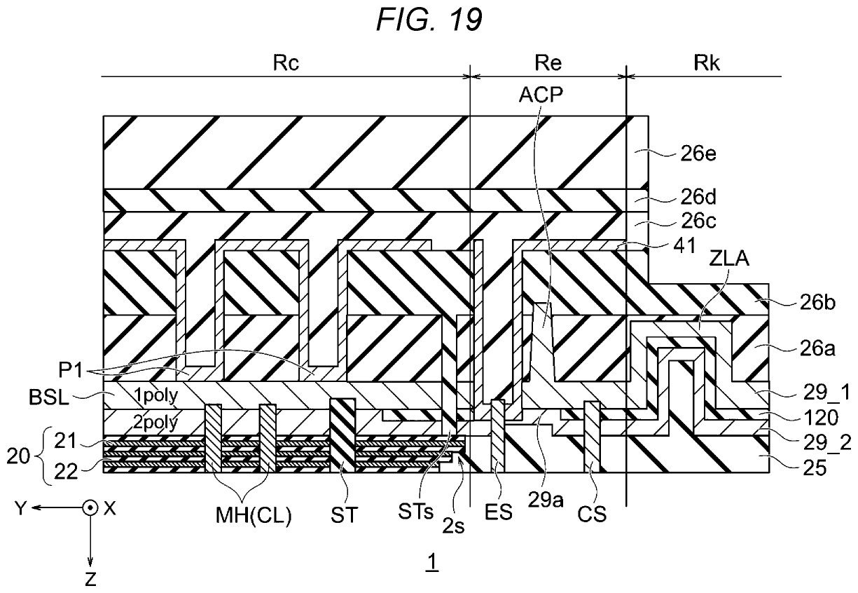

Next, as illustrated in FIG. 19, the insulating film 26c is formed on the metal layer 41. The holes or grooves formed on the backing pads P1 and the edge seal ES are filled with the insulating film 26c. For example, a silicon oxide film such as a TEOS film is used for the insulating film 26c.

Next, the insulating films 26d and 26e are formed on the insulating film 26c. For example, the insulating film such as silicon nitride film is used for the insulating film 26d. For example, the insulating film such as a polyimide film is used for the insulating film 26e.

Thereafter, the kerf area Rk is cut by a dicing cutter or the like, so that the semiconductor wafer is fragmented into the semiconductor chips. In this manner, the semiconductor device 1 is completed.

According to the present embodiment, the static elimination plug ACP is provided in the edge seal area Re. The static elimination plug ACP projects from the conductive film 29 to the substrate 100, and the tip thereof is in contact with the substrate 100. In the step of forming the memory holes MH and the slits ST illustrated in FIG. 13, the static elimination plug ACP electrically connects the conductive films 29_1 and 29_2 (i.e., the source layer BSL) to the substrate 100. Accordingly, the static elimination plug ACP can release the charges accumulated in the conductive films 29_1 and 29_2 to the substrate 100 in the step of forming the memory holes MH and the slits ST. Accordingly, in the step of forming the deep holes or grooves such as the memory holes MH or the slits ST, arcing from the conductive films 29_1 and 29_2 can be prevented.

In addition, since the static elimination plug ACP is present, it is not required to connect the conductive film 29 to the substrate in the bevel area of the edge seal area Re or the kerf area Rk for grounding. Accordingly, semiconductor chips can be scaled down, and the manufacturing cost can be reduced.

### Second Embodiment

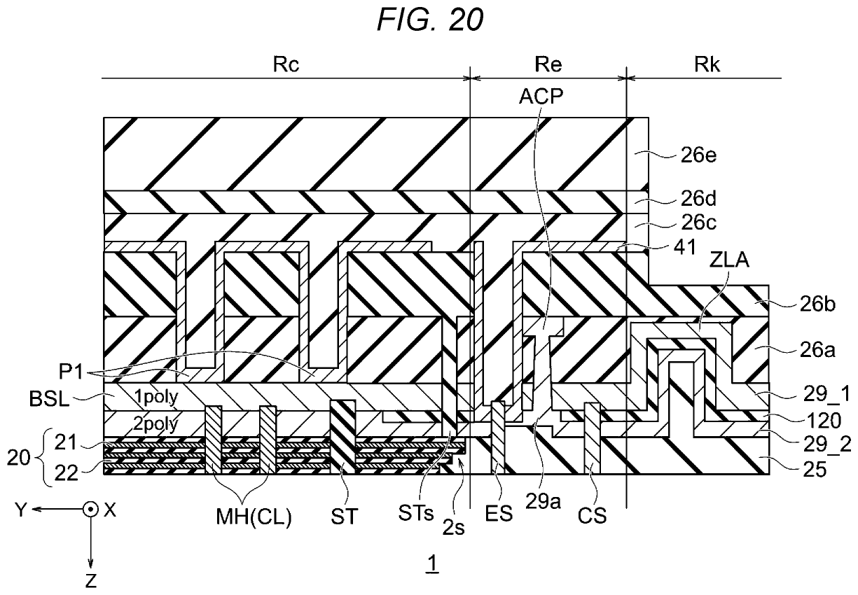

FIG. 20 is a cross-sectional view illustrating a configuration example of a semiconductor device 1 according to a second embodiment. The second embodiment is different from the first embodiment in that the static elimination plug ACP is configured with the conductive film 29_2 separated farther from the insulating films 26a and 26b than the conductive film 29_1. The conductive film 29_2 of the static elimination plug ACP penetrates the conductive film 29_1 and is in contact with the insulating films 26a and 26b.

The width of the static elimination plug ACP in the direction substantially perpendicular to the Z direction (the Y direction) becomes narrower as approaching the insulating films 26a and 26b from the conductive film 29_1 or 29_2. That is, the side surface of the static elimination plug ACP has a forward taper and has a tapered shape. However, a width of a tip of the static elimination plug ACP becomes wider, and thus has a shape of a hammer head.

In addition, the width of the static elimination plug ACP in the Y direction is preferably equal to or less than twice of a film thickness of the conductive film 29_2. When the film thickness of the conductive film 29_2 is, for example, about 100 nm, the width of the static elimination plug ACP is preferably about 200 nm or less. Accordingly, the material of the conductive film 29_2 can fill the groove of the static elimination plug ACP, and thus the conductive film 29_2 is not much recessed and becomes relatively flat. Accordingly, the interlayer insulating film 25 formed on the conductive film 29_2 becomes relatively flat, and thus the flattening step (i.e., the CMP step) can be omitted.

In this manner, the static elimination plug ACP may be formed by the conductive film 29_2.

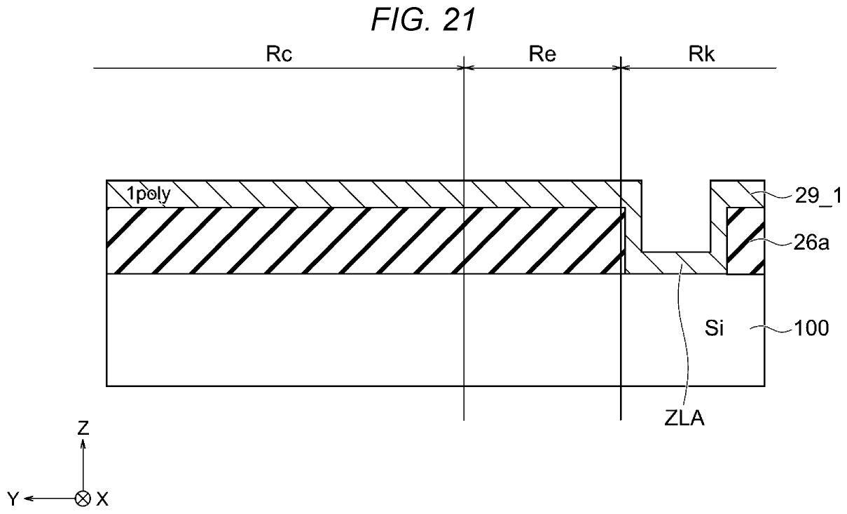

FIGS. 21 to 23 are cross-sectional views illustrating examples of a manufacturing method of the semiconductor device according to the second embodiment. In the manufacturing method according to the second embodiment, the static elimination plug ACP is not formed in a step of forming the conductive film 29_1 of FIG. 10, but the static elimination plug ACP may be formed in the step of forming the conductive film 29_1 of FIG. 12.

For example, as illustrated in FIG. 21, the conductive film 29_1 is formed.

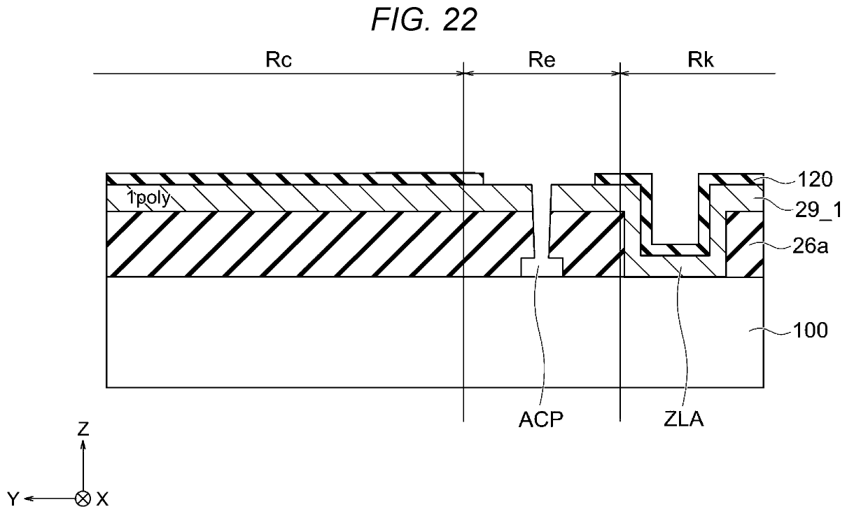

Next, as illustrated in FIG. 22, after the insulating film 120 is formed on the conductive film 29_1, by using the lithography technique and the etching technique, the conductive film 29_1 and the insulating film 26a in the formation area of the static elimination plug ACP are processed. Accordingly, as illustrated in FIG. 22, the grooves are formed in the formation area of the static elimination plug ACP of the edge seal area Re. The groove penetrates the conductive film 29_1 and the insulating film 26a and reaches the substrate 100.

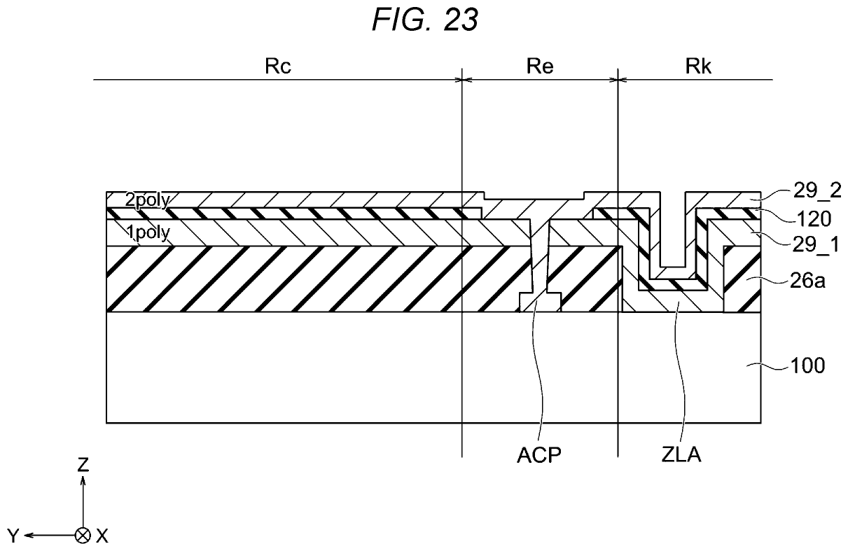

Next, by depositing the conductive film 29_2, the conductive film 29_2 fills the groove. Accordingly, as illustrated in FIG. 23, the static elimination plug ACP is formed by the conductive film 29_2 separated further from the substrate 100 than the conductive film 29_1. The other manufacturing steps of the second embodiment may be the same as those of the first embodiment.

The other configurations and manufacturing methods of the second embodiment may be the same as those of the first embodiment. Therefore, the second embodiment can exhibit the same effect as the first embodiment.

### Third Embodiment

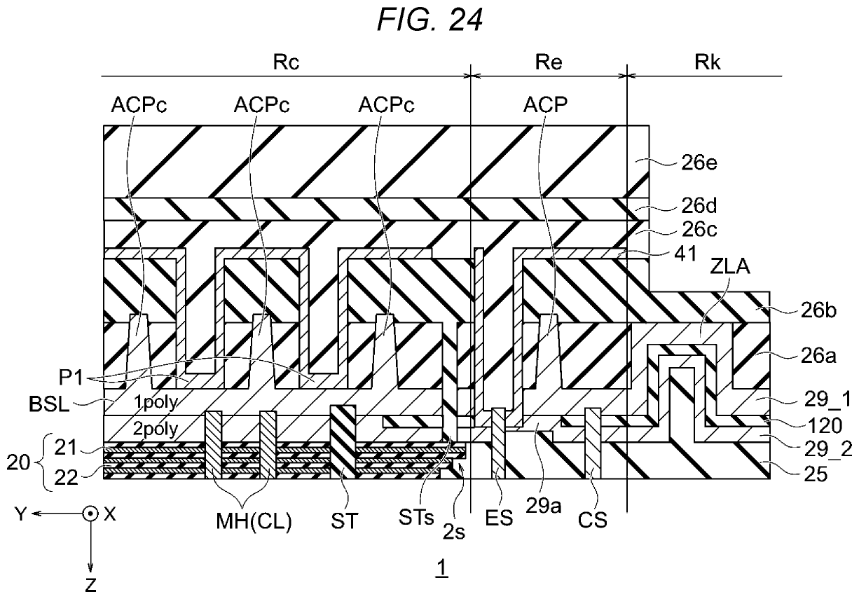

FIG. 24 is a cross-sectional view illustrating a configuration example of a semiconductor device 1 according to a third embodiment. The semiconductor device 1 according to the third embodiment is different from that in the first embodiment in that static elimination plugs ACPc are also provided in the chip area Rc. The static elimination plugs ACPc are provided between the source layer BSL and the insulating films 26a and 26b in the chip area Rc. The static elimination plug ACPc may have the same configuration as the static elimination plug ACP in the edge seal area Re and is formed in the same manufacturing step. The static elimination plug ACPc is configured with the same material as the static elimination plug ACP in the edge seal area Re. The static elimination plugs ACPc are provided so as not to be overlapped with the backing pads P1 in a plan view seen from the Z direction.

Since the static elimination plugs ACPc are also provided in the chip area Rc, in the step of forming the memory holes MH and the slits ST, the conductive films 29_1 and 29_2 are connected to the substrate 100 with a still lower resistance. Accordingly, the charges accumulated in the conductive films 29_1 and 29_2 are easily discharged to the substrate 100. Accordingly, arcing in the conductive films 29_1 and 29_2 can be more surely prevented.

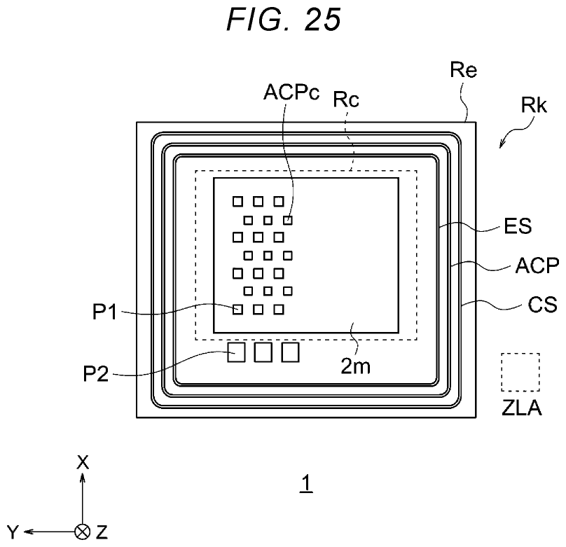

FIG. 25 is a plan view illustrating a configuration example of the semiconductor device 1 according to the third embodiment. As illustrated in FIG. 25, the static elimination plugs ACPc may correspond to the backing pads P1. The static elimination plugs ACPc may be substantially evenly located between the plurality of backing pads P1 adjacent to each other in the X direction and/or the Y direction. The number of static elimination plugs ACPc is not particularly limited.

The other configurations of the third embodiment may be the same as those of the first embodiment. Therefore, the third embodiment can exhibit the same effect as the first embodiment. In addition, the third embodiment may be combined with the second embodiment. That is, the static elimination plug ACPc may be configured with the conductive film 29_2.

### Fourth Embodiment

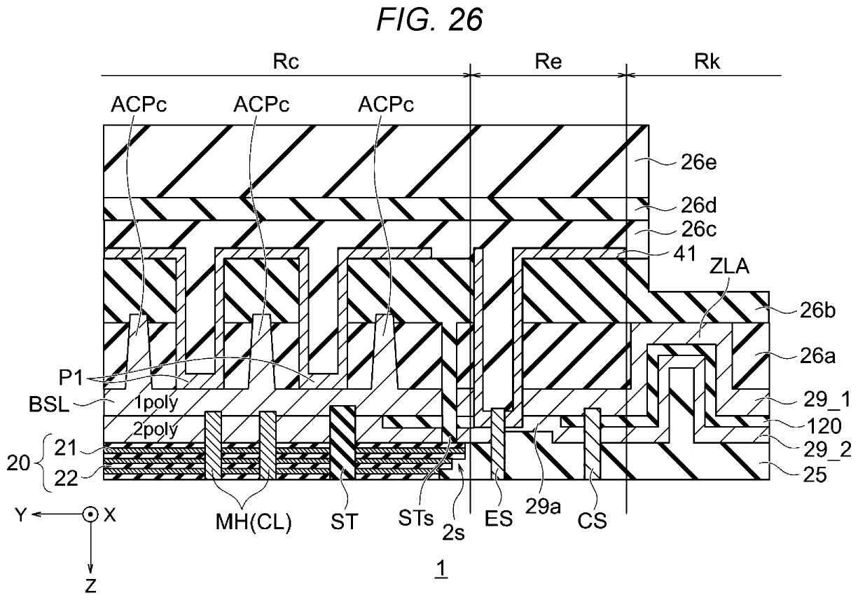

FIG. 26 is a cross-sectional view illustrating a configuration example of a semiconductor device 1 according to a fourth embodiment. The semiconductor device 1 according to the fourth embodiment includes the static elimination plugs ACPc in the chip area Rc in the third embodiment, but the static elimination plug ACP in the edge seal area Re is omitted. In this manner, when the static elimination plugs ACPc in the chip area Rc are provided, the static elimination plug ACP in the edge seal area Re may not be provided and may be omitted. The other configurations of the fourth embodiment may be the same as those of the third embodiment. Accordingly, the fourth embodiment can exhibit the same effect as the third embodiment. In addition, the fourth embodiment may be combined with the first or second embodiment.

### Fifth Embodiment

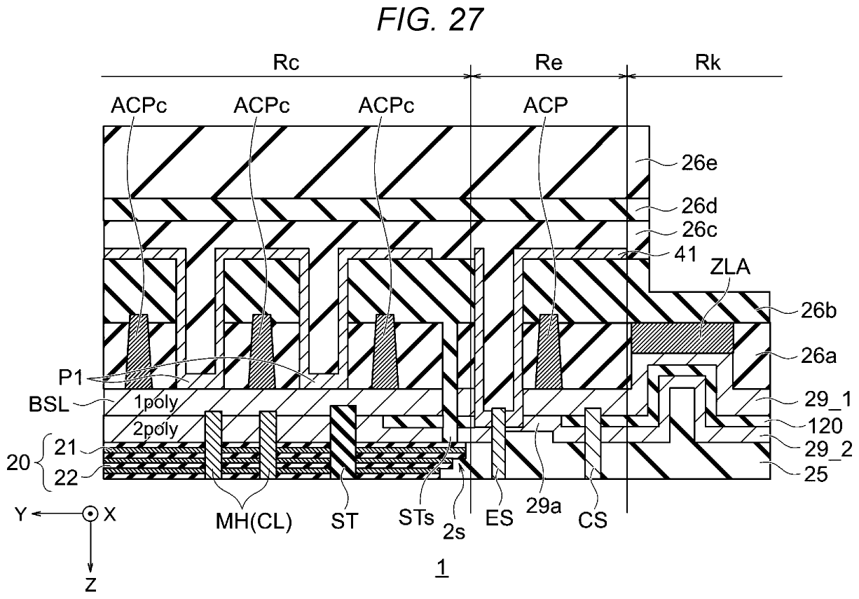

FIG. 27 is a cross-sectional view illustrating a configuration example of a semiconductor device 1 according to a fifth embodiment. In the semiconductor device 1 according to the fifth embodiment, the static elimination plugs ACP and/or ACPc are configured with a semiconductor single crystal material including impurities. For example, the static elimination plugs ACP and/or ACPc are configured with epitaxially grown silicon single crystals. In this case, after the substrate 100 is exposed as illustrated in FIG. 9, silicon single crystals are grown on the exposed substrate 100 by using an epitaxial growth method. At this point, silicon single crystals are grown while introducing impurities (e.g., boron). Accordingly, the electrically conductive static elimination plugs ACP and/or ACPc may be formed. Further, the silicon single crystal is formed also in a portion of the alignment mark ZLA, but causes no problem.

The other configurations of the fifth embodiment may be the same as those of the third embodiment. Accordingly, the fifth embodiment can exhibit the same effect as the third embodiment. In addition, by using epitaxially grown silicon single crystals for the static elimination plug ACP, it is not required to fill the groove of the static elimination plug ACP with the conductive films 29_1 and 29_2. Accordingly, the conductive films 29_1 and 29_2 can be formed to be relatively flat.

In addition, the fifth embodiment may be combined with the first, second, or fourth embodiment. When the fifth embodiment is applied to the second embodiment, in a step illustrated in FIG. 22, silicon single crystals may be grown on the exposed substrate 100 by using the epitaxial growth method.

### Sixth Embodiment

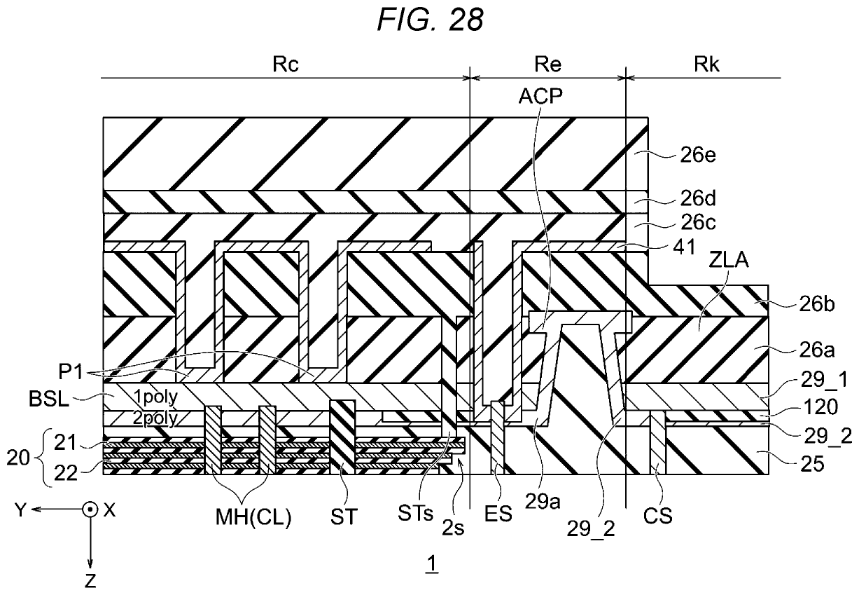

FIG. 28 is a cross-sectional view illustrating a configuration example of a semiconductor device 1 according to a sixth embodiment. In the semiconductor device 1 according to the sixth embodiment, the width of the static elimination plug ACP in the Y direction becomes wider than twice of the film thickness of the conductive film 29_2. Accordingly, the conductive film 29_2 covers an inner wall of the groove of the static elimination plug ACP, and the interlayer insulating film 25 is provided via the conductive film 29_2 on an inner side of the groove. Accordingly, a contact area between the conductive film 29_2 and the insulating films 26a and 26b becomes large, and thus it is less likely that the conductive film 29_2 is peeled off from the insulating films 26a and 26b. In addition, in the step of forming the memory holes MH or the slits ST, a contact area between the conductive film 29_2 and the substrate 100 becomes large, and a contact resistance therebetween can be reduced. Accordingly, a static elimination effect of the static elimination plug ACP is improved.

In addition, the groove of the static elimination plug ACP is not filled with the material of the conductive film 29_2, and thus the static elimination plug ACP can function as the alignment mark. In this case, it is not required to provide the alignment mark ZLA in the kerf area Rk.

The other configurations of the sixth embodiment may be the same as those of the second embodiment. Accordingly, the sixth embodiment can exhibit the same effect as the second embodiment. In addition, the sixth embodiment may be combined with the first, third, or fourth embodiment.

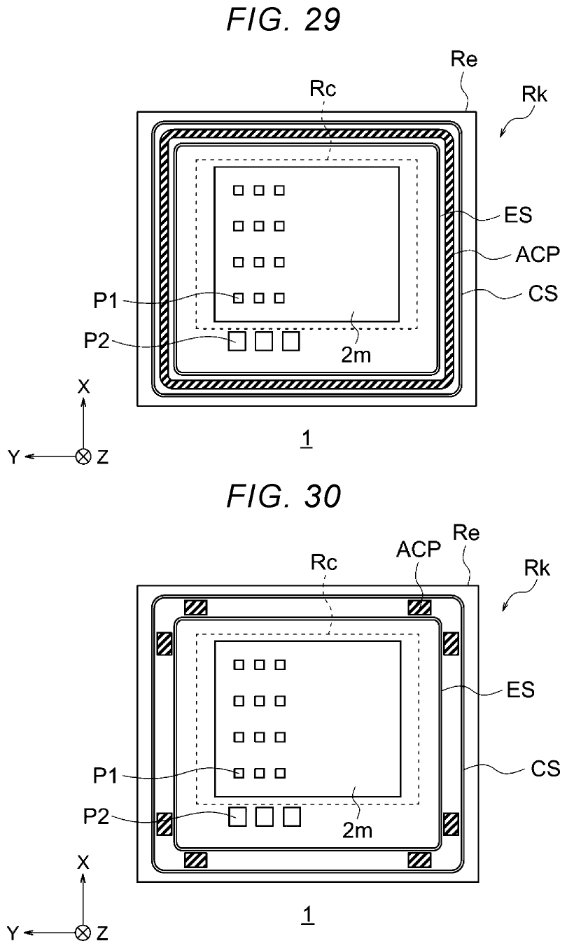

FIGS. 29 and 30 are plan views illustrating configuration examples of the semiconductor device 1 according to the sixth embodiment. As illustrated in FIG. 29, the static elimination plug ACP according to the sixth embodiment may surround the entire chip area Rc.

Alternately, since the width of the static elimination plug ACP according to the sixth embodiment is relatively wide, the contact area between the conductive film 29_2 and the substrate 100 can become relatively wide, and the contact area between the conductive film 29_2 and the insulating films 26a and 26b can become relatively wide. Therefore, as illustrated in FIG. 30, the static elimination plug ACP may be provided in a portion around the chip area Rc. Also in this case, the static elimination plug ACP can be connected to the substrate 100 with the sufficiently low resistance and sufficiently exhibit the static elimination effect. In addition, the static elimination plug ACP has a large contact area with the insulating films 26a and 26b, and it is not likely that the static elimination plug ACP is peeled off from the insulating films 26a and 26b.

In addition, the static elimination plugs ACP are preferably located substantially evenly around the chip area Rc. For example, the static elimination plugs ACP are located substantially evenly corresponding to four corners in the chip area Rc. Accordingly, local concentration of charges in the conductive films 29_1 and 29_2 is prevented. Therefore, arcing in the conductive films 29_1 and 29_2 can be prevented.

### Seventh Embodiment

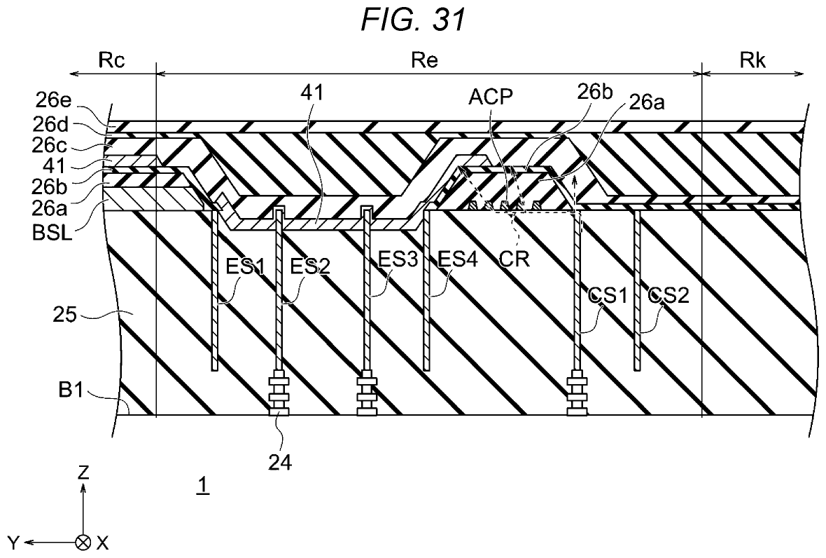

FIG. 31 is a cross-sectional view illustrating a configuration example of a semiconductor device 1 according to a seventh embodiment. In the seventh embodiment, the plurality of static elimination plugs ACP are located in the Y direction, but under the static elimination plugs ACP, the interlayer insulating film 25 is provided, and the conductive film 29 is not provided. That is, the plurality of static elimination plugs ACP are provided between the interlayer insulating film 25 and the insulating film 26a, and are in contact with the interlayer insulating film 25 and the insulating film 26a. The plurality of static elimination plugs ACP are not connected to each other by the conductive film 29. That is, the plurality of static elimination plugs ACP are provided on the interlayer insulating film 25, and isolated from each other. The other configurations of the seventh embodiment may be the same as those of the first embodiment.

The static elimination plug ACP according to the seventh embodiment can more effectively warp a crack CR developed in a direction of the chip area Rc (i.e., the Y direction) from the outside of the semiconductor device 1 in another direction.

As illustrated in FIG. 7, when the plurality of static elimination plugs ACP are connected to each other by the conductive film 29 provided below the static elimination plugs ACP, that is, when the plurality of static elimination plugs ACP are provided on the conductive film 29, it is highly likely that the crack CR that develops in the Z direction along the crack stopper CS1 develops along an interface between the conductive film 29 and the interlayer insulating film 25 in the direction of the chip area Rc (i.e., the Y direction). In this case, the static elimination plug ACP does not function as the crack stopper.

In addition, since the plurality of static elimination plugs ACP are integrally configured with the same material as the conductive film 29, it is difficult for each static elimination plug ACP to function as the crack stopper.

In contrast, according to the seventh embodiment, the plurality of static elimination plugs ACP are provided on the interlayer insulating film 25 and physically isolated from each other. Therefore, as illustrated in FIG. 31, even if the crack CR develops along an interface between the insulating film 26a and the interlayer insulating film 25 in the direction of the chip area Rc (i.e., the Y direction), the crack CR can develop diagonally upward (i.e., an inclination direction between Z and Y) along a taper-shaped side surface of each static elimination plug ACP. Since the plurality of static elimination plugs ACP each function as the crack stopper, respectively, a chance of warping the crack CR diagonally upward is increased, and the likeliness of developing the crack CR toward the chip area Rc (i.e., in the Y direction) can be reduced. In this manner, the static elimination plug ACP according to the seventh embodiment has not only the static elimination function in the step of forming the memory holes MH and the slits ST but also the function as the crack stopper in the dicing step or the like.

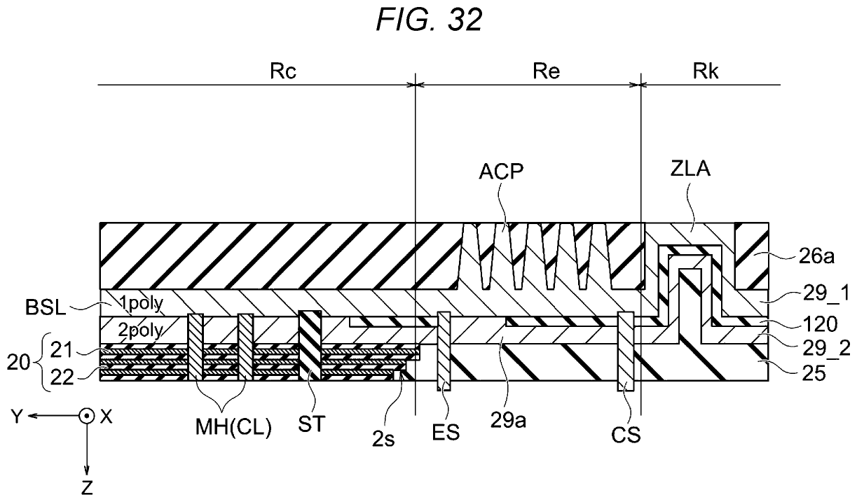

FIGS. 32 to 35 are cross-sectional views illustrating examples of the manufacturing method of the semiconductor device according to the seventh embodiment. Further, for convenience, FIGS. 32 to 35 conceptually illustrate the configurations illustrated in FIG. 31 in accordance with the drawings of the manufacturing method of the first embodiment. It is noted that FIGS. 32 to 35 illustrate the plurality of static elimination plugs ACP.

First, after the steps described with reference to FIGS. 8 to 14 are performed, the substrate 100 is removed. Accordingly, a structure illustrated in FIG. 32 is obtained.

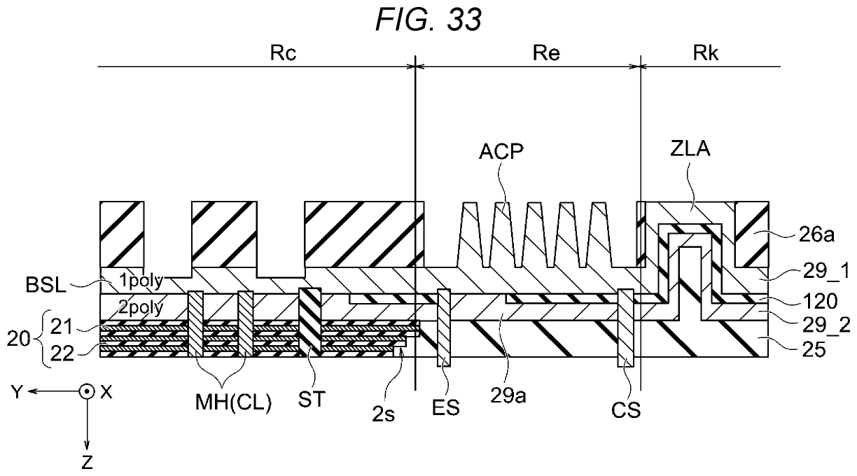

Next, by using the lithography technique and the etching technique, as illustrated in FIG. 33, the interlayer insulating film 26a on the static elimination plugs ACP, the edge seal ES, and the crack stopper CS is selectively removed. Accordingly, the plurality of static elimination plugs ACP and the conductive film 29_1 under the static elimination plugs ACP are exposed.

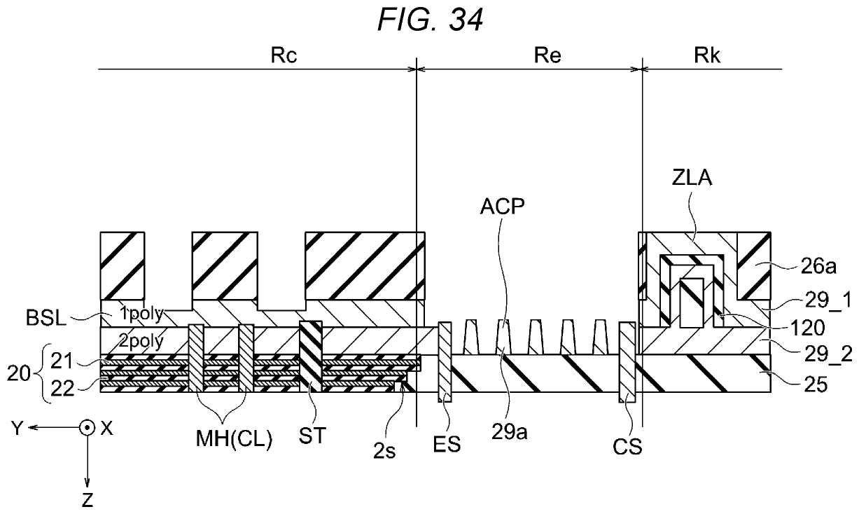

Next, by using the lithography technique and the etching technique, the plurality of static elimination plugs ACP and the conductive films 29_1 and 29_2 under the static elimination plugs ACP are anisotropically etched. Since the static elimination plugs ACP and the conductive films 29_1 and 29_2 are configured with the same material (e.g., polysilicon), while a convex shape of each static elimination plug ACP is maintained, the conductive films 29_1 and 29_2 under the static elimination plugs ACP are removed. The static elimination plugs ACP and the conductive films 29_1 and 29_2 are etched until the interlayer insulating film 25 is exposed. Therefore, while the convex shape of each static elimination plug ACP is maintained, the conductive films 29_1 and 29_2 under the static elimination plugs ACP are removed, and the conductive films 29_1 and 29_2 on the edge seal ES and the crack stopper CS can be removed. Accordingly, as illustrated in FIG. 34, the plurality of static elimination plugs ACP remain located on the interlayer insulating film 25 in a state of being physically isolated from each other. At this point, the end portions of the edge seal ES and the crack stopper CS are exposed.

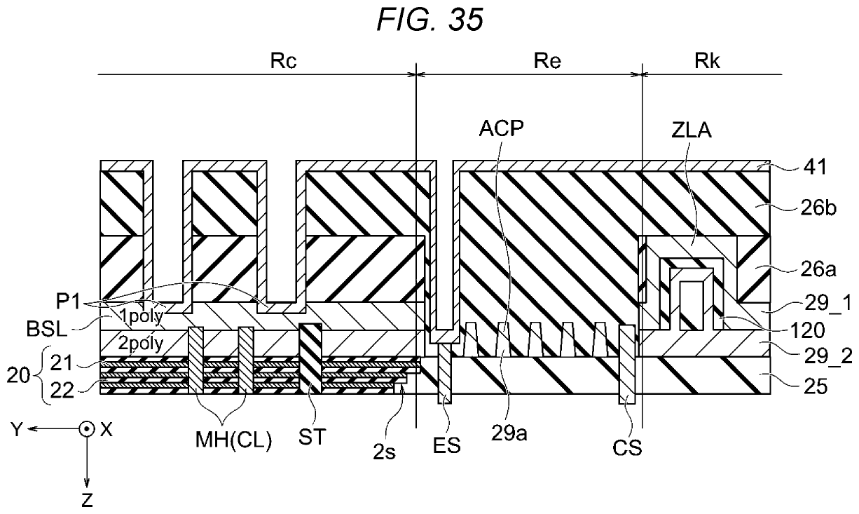

Thereafter, after the steps described with reference to FIGS. 16 and 17 are performed, the insulating film 26b and the conductive film 41 are formed as illustrated in FIG. 35. Thereafter, as illustrated in FIGS. 18 and 19, by using the lithography technique and the etching technique, the conductive film 41 is processed, and further the insulating films 26c to 26e are formed, to complete the semiconductor device 1 according to the seventh embodiment.

The other configurations of the seventh embodiment may be the same as those of the first embodiment. Accordingly, the seventh embodiment can exhibit the same effect as the first embodiment. In addition, the seventh embodiment may be combined with any one of the second to sixth embodiments.

### Eighth Embodiment

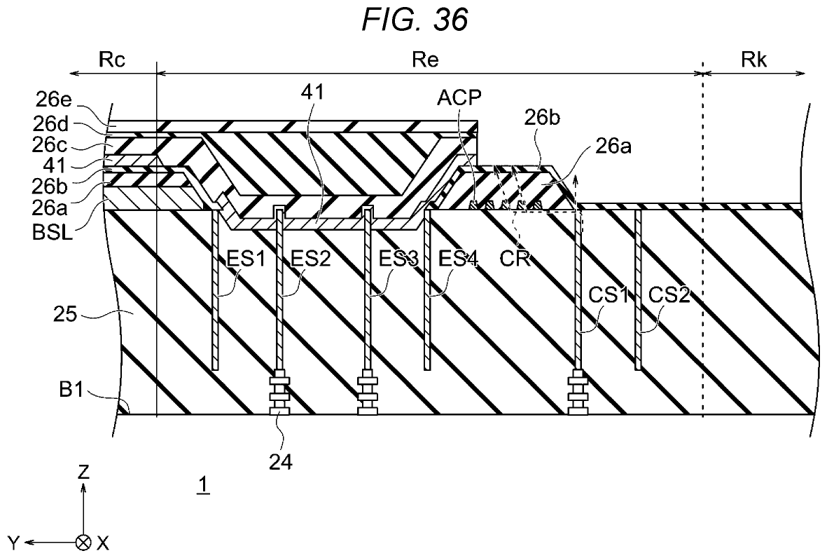

FIG. 36 is a cross-sectional view illustrating a configuration example of a semiconductor device 1 according to an eighth embodiment. In the eighth embodiment, the insulating films 26c to 26e above the static elimination plugs ACP are removed. That is, the insulating films 26c to 26e are provided above the edge seals ES1 to ES4, but are not provided on the static elimination plugs ACP. Accordingly, when the crack CR develops along the side surface of the static elimination plug ACP diagonally upward, the crack CR can be prevented from developing further toward the chip area Rc along the insulating films 26c to 26e. Further, the insulating films 26c to 26e in the kerf area Rk may be also removed.

### Example of Application to NAND-Type Flash Memory

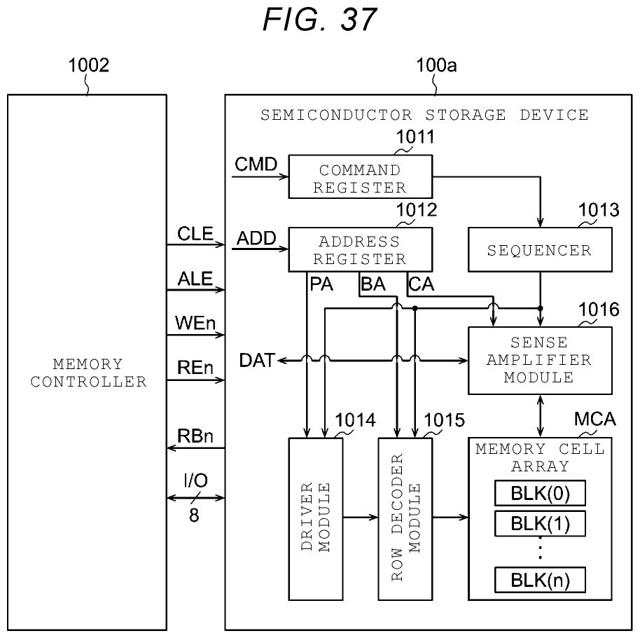

FIG. 37 is a block diagram illustrating a configuration example of a semiconductor storage device to which any one of the embodiments is applied. The semiconductor storage device 100a is a NAND-type flash memory that can store data in a nonvolatile manner and is controlled by an external memory controller 1002. The communication between the semiconductor storage device 100a and the memory controller 1002 supports, for example, a NAND interface standard. The semiconductor device 1 is applicable to the semiconductor storage device 100a.

As illustrated in FIG. 37, the semiconductor storage device 100a includes, for example, a memory cell array MCA, a command register 1011, an address register 1012, a sequencer 1013, a driver module 1014, a row decoder module 1015, and a sense amplifier module 1016.

The memory cell array MCA includes a plurality of blocks BLK(0) to BLK(n) (n is an integer of 1 or more). The block BLK is a set including a plurality of memory cells that can store data in a nonvolatile manner, and is used, for example, as an erasing unit of data. In addition, a plurality of bit lines and a plurality of word lines are provided in the memory cell array MCA. For example, each memory cell is associated with one bit line and one word line. Detailed configurations of the memory cell array MCA are described below.

The command register 1011 stores a command CMD that the semiconductor storage device 100a receives from the memory controller 1002. The command CMD includes an instruction, for example, for causing the sequencer 1013 to perform a read operation, a write operation, an erasing operation, or the like.

The address register 1012 stores address information ADD that the semiconductor storage device 100a receives from the memory controller 1002. The address information ADD includes, for example, a block address BA, a page address PA, and a column address CA. For example, the block address BA, the page address PA, and the column address CA are used for selecting the block BLK, the word line, and the bit line, respectively.

The sequencer 1013 controls the entire operations of the semiconductor storage device 100a. For example, the sequencer 1013 controls the driver module 1014, the row decoder module 1015, the sense amplifier module 1016, and the like based on the command CMD stored in the command register 1011 and performs the read operation, the write operation, the erasing operation, and the like.

The driver module 1014 generates a voltage to be used for the read operation, the write operation, the erasing operation, and the like. Also, the driver module 1014 applies the generated voltage to a signal line corresponding to the selected word line, for example, based on the page address PA stored in the address register 1012.

The row decoder module 1015 includes a plurality of row decoders. The row decoder selects one block BLK in the corresponding memory cell array MCA based on the block address BA stored in the address register 1012. Also, the row decoder transmits, for example, the voltage applied to the signal line corresponding to the selected word line to the selected word line in the selected block BLK.

The sense amplifier module 1016 applies a desired voltage to each bit line according to write data DAT received from the memory controller 1002 in the write operation. In addition, in the read operation, the sense amplifier module 1016 determines data stored in the memory cell based on the voltage of the bit line and transmits a determination result to the memory controller 1002 as read data DAT.

The semiconductor storage device 100a and the memory controller 1002 described above may configure one semiconductor device in combination. Examples of the semiconductor device include a memory card such as an SDTM card, and a solid-state drive (SSD).

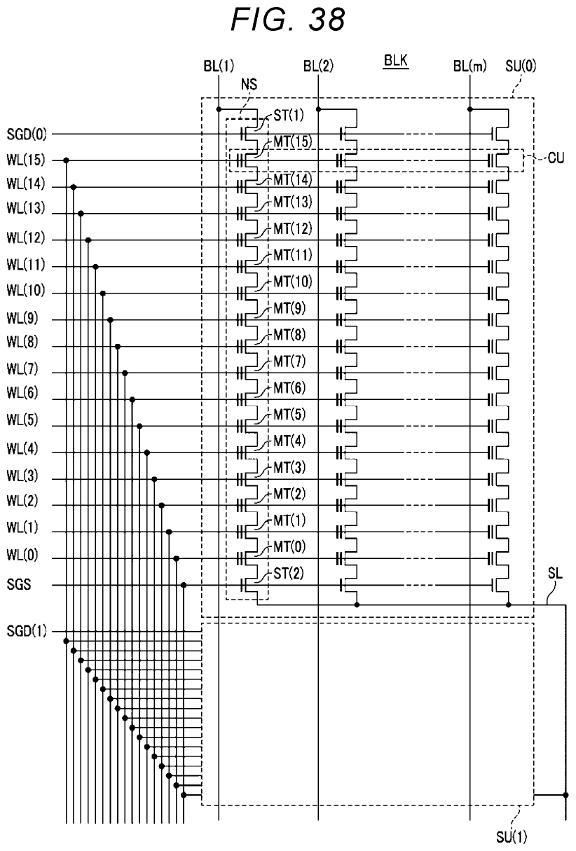

FIG. 38 is a circuit diagram illustrating an example of a circuit configuration of the memory cell array MCA. One block BLK among the plurality of blocks BLK in the memory cell array MCA is extracted. As illustrated in FIG. 38, the block BLK includes a plurality of string units SU(0) to SU(k) (k is an integer of 1 or more).

Each string unit SU includes a plurality of NAND strings NS respectively associated with the bit lines BL(0) to BL(m) (m is an integer of 1 or more). Each NAND string NS includes, for example, memory cell transistors MT(0) to MT(15) and select transistors ST(1) and ST(2). The memory cell transistor MT includes a control gate and a charge storage layer, and stores data in a nonvolatile manner. The select transistors ST(1) and ST(2) each are used for selecting the string units SU during various operations.

In each NAND string NS, the memory cell transistors MT(0) to MT(15) are connected to each other in series. A drain of the select transistor ST(1) is connected to the associated bit line BL, and a source of the select transistor ST(1) is connected to one end of the memory cell transistors MT(0) to MT(15) connected to each other in series. A drain of the select transistor ST(2) is connected to the other end of the memory cell transistors MT(0) to MT(15) connected to each other in series. A source of the select transistor ST(2) is connected to a source line SL.

In the same block BLK, the control gates of the memory cell transistors MT(0) to MT(15) are commonly connected to the word lines WL(0) to WL(15), respectively. The gates of the select transistors ST(1) in the string units SU(0) to SU(k) are commonly connected to select gate lines SGD(0) to SGD(k), respectively. The gates of the select transistors ST(2) are commonly connected to the select gate line SGS.

In the circuit configuration of the memory cell array MCA described above, the bit lines BL are shared by the NAND strings NS to which the same column address is allocated in each string unit SU. The source line SL is shared, for example, by the plurality of blocks BLK.

A set including the plurality of memory cell transistors MT connected to the common word line WL in one string unit SU is referred to as, for example, a cell unit CU. For example, a storage capacity of the cell unit CU including the memory cell transistors MT that each store 1 bit data is defined as “1 page data”. The cell unit CU may have a storage capacity of 2 page data or more according to the number of bits of data that the memory cell transistors MT each store.

Further, the memory cell array MCA that the semiconductor storage device 100a according to the present embodiment includes is not limited to the circuit configuration described above. For example, the number of memory cell transistors MT and the numbers of select transistors ST(1) and ST(2) that each NAND string NS includes may be any numbers, respectively. The number of string units SU that each block BLK includes may be any number.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a plurality of first electrode films stacked in a first direction and electrically isolated from each other;
a plurality of semiconductor members extending in the first direction through the plurality of first electrode films;
a first conductive film including a first surface and connected to the plurality of semiconductor members on the first surface;
a first insulating film spaced from the first conductive film on a second surface of the first conductive film opposite to the first surface;
a first edge member disposed in an edge area that surrounds an element area including the first electrode film, the semiconductor member, and the first conductive film; and
a conductive first plug provided between the first edge member and the element area in the edge area and is in contact with the first insulating film.

2. The semiconductor device according to claim 1,
wherein a width of the first plug in a direction substantially perpendicular to the first direction reduces in a direction from the first insulating film to the first conductive film.

3. The semiconductor device according to claim 1, further comprising:
a second edge member provided on an inner side of the first edge member to surround the element area and extends in the first direction in the edge area,
wherein the first plug is provided between the first edge member and the second edge member in the edge area when viewed from the first direction.

4. The semiconductor device according to claim 1,
wherein the first plug is provided between the first conductive film and the first insulating film in the edge area.

5. The semiconductor device according to claim 1,
wherein the first conductive film includes first and second conductive material layers stacked in the first direction,
the first conductive material layer is closer to the first insulating film than the second conductive material layer, and
the first plug is configured with the first conductive material layer.

6. The semiconductor device according to claim 1,
wherein the first conductive film includes first and second conductive material layers stacked in the first direction,
the second conductive material layer is farther from the first insulating film than the first conductive material layer, and
the first plug is configured with the second conductive material layer.

7. The semiconductor device according to claim 1, further comprising:
a second plug provided in a cut area provided outside the edge area with respect to the element area, in contact with the first insulating film, and including the same material as the first conductive film.

8. The semiconductor device according to claim 1, further comprising:
a third plug provided between the first conductive film and the first insulating film in the element area and including the same material as the first conductive film.

9. The semiconductor device according to claim 1,
wherein the first plug is provided between the first insulating film and a second insulating film below the first insulating film.

10. A manufacturing method of a semiconductor device, comprising:
forming an insulating film on a first substrate;
forming a first groove penetrating the insulating film to the first substrate;
forming a first conductive film on the insulating film;
forming a first plug that electrically connects the first conductive film to the first substrate by filling the first groove with a material of the first conductive film;
forming, above the first conductive film, a plurality of first electrode films stacked in a first direction and electrically isolated from each other and a plurality of semiconductor members extending in the first direction through the plurality of first electrode films;
forming a first edge member in an edge area that surrounds an element area including the first electrode film, the semiconductor member, and the first conductive film;
removing the first substrate to expose the first plug; and
forming a first insulating film on the first plug and the insulating film.

11. The manufacturing method of a semiconductor device according to claim 10, further comprising:
selectively removing the first insulating film on the first plug and the first edge member in the edge area; and
etching the first plug and the first conductive film on the first edge member and removing the first conductive film on the first edge member while maintaining a shape of the first plug, after the first substrate is removed to expose the first plug, before the first insulating film is formed.

12. The manufacturing method of a semiconductor device according to claim 10,
wherein the first conductive film includes first and second conductive material layers stacked in the first direction,
the first conductive material layer is closer to the first insulating film than the second conductive material layer, and
the first plug is configured with the first conductive material layer.

13. The manufacturing method of a semiconductor device according to claim 10,
wherein the first conductive film includes first and second conductive material layers stacked in the first direction,
the second conductive material layer is farther from the first insulating film than the first conductive material layer, and
the first plug is configured with the second conductive material layer.

14. The manufacturing method of a semiconductor device according to claim 10, wherein the first plug is provided between the first conductive film and the first insulating film in the edge area.
